(19) United States
(12) Patent Application Publication
(10) Pub. No.: US 2026/0068593 A1
(43) Pub. Date: Mar. 5, 2026

(54) DEPOSITION METHOD, DEPOSITION APPARATUS, AND ELECTRONIC DEVICE MANUFACTURED BY USING THE DEPOSITION APPARATUS

(71) Applicant: Samsung Display Co., LTD., Yongin-si (KR)

(72) Inventors: Sung Woon KIM, Yongin-si (KR); Duck Jung LEE, Yongin-si (KR)

(21) Appl. No.: 19/192,650

(22) Filed: Apr. 29, 2025

(30) Foreign Application Priority Data
Aug. 28, 2024 (KR) 10-2024-0115679

(51) Int. Cl. H01L 21/68; C23C 14/04; C23C 14/50; C23C 14/54; H01L 21/66; H01L 21/683; H10K 59/12; H10K 71/16

(52) U.S. Cl. CPC H01L 21/682; C23C 14/042; C23C 14/50; C23C 14/54; H10K 59/1201; H10K 71/164

(57) ABSTRACT

Provided are a deposition method, a deposition apparatus, and an electronic device manufactured by using the deposition apparatus. The deposition method includes forming a plurality of sensors on a substrate or a deposition mask which measure gaps between the substrate and the deposition mask, positioning the substrate on the deposition mask, measuring the gaps between the substrate and the deposition mask using the plurality of sensors, adjusting a parallelism between the substrate and the deposition mask based on the measuring of the gaps between the substrate and the deposition mask, and providing a deposition material onto the substrate through the deposition mask, wherein providing the deposition material forms a deposition material layer on the substrate.

This application claims priority to Korean Patent Application No. 10-2024-0115679, filed on Aug. 28, 2024, and all the benefits accruing therefrom under 35 U.S.C. § 119, the content of which in its entirety is herein incorporated by reference.

### BACKGROUND

### 1. Field

The present disclosure relates to a deposition method, a deposition apparatus, and an electronic device manufactured by using the deposition apparatus.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user.

In the case of wearable devices such as, for example, HMD devices or AR glasses, providing a high-resolution image, e.g., an image with a resolution of about 3000 PPI (pixels per inch) or higher, may enable users to use the wearable devices for a long time without symptoms of dizziness. To this end, an organic light emitting diode on silicon (OLEDoS) technology used for high-resolution small organic light emitting display devices has attracted attention. The OLEDOS is a technology in which an organic light emitting diodes (OLED) are disposed on a semiconductor substrate on which complementary metal oxide semiconductor (CMOS) elements are disposed.

Some approaches for manufacturing a display panel with a high resolution of about 3000 PPI or higher may use a high-resolution deposition mask. For example, the deposition mask may be manufactured by forming a membrane having a plurality of pixel openings on a substrate such as, for example, a silicon wafer, and partially removing the substrate to form cell openings that expose the pixel openings.

The deposition mask may be used in a deposition process for forming light emitting layers of sub-pixels on a backplane substrate. While the deposition process is being performed, the backplane substrate may be disposed on the deposition mask, and a deposition source for providing a vapor deposition material may be disposed under the deposition mask. However, if warpage occurs during the manufacturing process of the deposition mask, parallelism between the backplane substrate and the deposition mask may deteriorate, such that the pixel position accuracy (PPA) of the light emitting layers formed on the backplane substrate may deteriorate, and a color mixing phenomenon may occur between the sub-pixels.

### SUMMARY

Aspects and features of embodiments of the present disclosure provide a deposition method and a deposition apparatus capable of improving parallelism between a substrate and a deposition mask, and an electronic device manufactured by using the deposition apparatus.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

In accordance with an aspect of the present disclosure, a deposition method may include forming a plurality of sensors on a substrate or a deposition mask which measure gaps between the substrate and the deposition mask, positioning the substrate on the deposition mask, measuring the gaps between the substrate and the deposition mask using the plurality of sensors, adjusting a parallelism between the substrate and the deposition mask based on the measuring of the gaps between the substrate and the deposition mask, and providing a deposition material onto the substrate through the deposition mask, wherein providing the deposition material forms a deposition material layer on the substrate.

In accordance with some embodiments of the present disclosure, the substrate may include display cell regions, a scribe lane region disposed between the display cell regions, and an edge region. Each of the plurality of sensors may include a measurement electrode formed on the scribe lane region, a contact pad formed on the edge region, and a wiring formed on the scribe lane region and connecting the measurement electrode and the contact pad.

In accordance with some embodiments of the present disclosure, each of the gaps between the substrate and the deposition mask may be measured based on a capacitance between the measurement electrode and the deposition mask.

In accordance with some embodiments of the present disclosure, The deposition method may further include forming a plurality of spacers on the deposition mask. Each of the gaps between the substrate and the deposition mask may be measured based on a capacitance between the measurement electrode and a respective spacer comprised among the plurality of spacers.

In accordance with some embodiments of the present disclosure, the substrate may include display cell regions, a scribe lane region disposed between the display cell regions, and an edge region. Each of the plurality of sensors may include a first contact electrode and a second contact electrode formed on the scribe lane region, a first contact pad and a second contact pad formed on the edge region, and a first wiring and a second wiring formed on the scribe lane region wherein the first wiring connects the first contact electrode and the first contact pad, and the second wiring connects the second contact electrode and the second contact pad.

In accordance with some embodiments of the present disclosure, the deposition method may further include forming a plurality of spacers on the deposition mask. Each of the gaps between the substrate and the deposition mask may be measured by whether there is an electrical connection between the first and second contact electrodes and the plurality of spacers.

In accordance with some embodiments of the present disclosure, the deposition mask may include mask cell regions, a grid region disposed between the mask cell regions, and an edge region. Each of the plurality of sensors may include a measurement electrode formed on the grid region, a contact pad formed on the edge region, and a wiring formed on the grid region and connecting the measurement electrode and the contact pad.

In accordance with some embodiments of the present disclosure, each of the gaps between the substrate and the deposition mask may be measured based on a capacitance between the measurement electrode and the substrate.

In accordance with some embodiments of the present disclosure, the positioning of the substrate on the deposition mask may include loading the substrate and the deposition mask onto a substrate chuck and a mask chuck, respectively, such that the substrate and the deposition mask face each other, adjusting a parallelism between the substrate chuck and the mask chuck, aligning the substrate and the deposition mask with each other, and adjusting a gap between the substrate chuck and the mask chuck such that the substrate is positioned on the deposition mask.

In accordance with some embodiments of the present disclosure, the adjusting of the parallelism between the substrate chuck and the mask chuck may include measuring gaps between the substrate chuck and the mask chuck using gap sensors arranged on the substrate chuck, and adjusting an inclination of the substrate chuck based on the measuring of the gaps between the substrate chuck and the mask chuck.

In accordance with some embodiments of the present disclosure, the adjusting of the parallelism between the substrate chuck and the mask chuck may include primarily measuring gaps between the substrate chuck and the mask chuck using first gap sensors, primarily adjusting an inclination of the substrate chuck based on the primarily measuring of the gaps, secondarily measuring gaps between the substrate chuck and the mask chuck using second gap sensors having a resolution higher than a resolution of the plurality of first gap sensors, and secondarily adjusting the inclination of the substrate chuck based on the secondarily measuring of the gaps.

In accordance with some embodiments of the present disclosure, the adjusting of the parallelism between the substrate chuck and the mask chuck may further include adjusting the gap between the substrate and the deposition mask to a first gap, and adjusting the gap between the substrate and the deposition mask to a second gap smaller than the first gap. The primarily measuring of the gaps between the substrate chuck and the mask chuck may be performed after the adjusting of the gap between the substrate and the deposition mask to the first gap, and the secondarily measuring of the gaps between the substrate chuck and the mask chuck may be performed after the adjusting of the gap between the substrate and the deposition mask to the second gap.

In accordance with some embodiments of the present disclosure, the parallelism between the substrate and the deposition mask may be adjusted by adjusting an inclination of a substrate chuck on which the substrate is loaded.

In accordance with another aspect of the present disclosure, a deposition apparatus may include a deposition source providing a deposition material onto a substrate, a mask chuck disposed above the deposition source and supporting a deposition mask, a substrate chuck disposed above the mask chuck and supporting the substrate such that the substrate faces the deposition mask, and a substrate chuck driver adjusting a position and an inclination of the substrate chuck in association with positioning the substrate on the deposition mask and adjusting a parallelism between the substrate and the deposition mask. A plurality of sensors for measuring gaps between the substrate and the deposition mask may be disposed on the substrate or the deposition mask, and the substrate chuck driver may adjust the inclination of the substrate chuck based on measurements of the gaps between the substrate and the deposition mask as provided by the plurality of sensors.

In accordance with some embodiments of the present disclosure, the substrate may include display cell regions, a scribe lane region disposed between the display cell regions, and an edge region. Each of the plurality of sensors may include a measurement electrode formed on the scribe lane region, a contact pad formed on the edge region, and a wiring disposed on the scribe lane region and connecting the measurement electrode and the contact pad.

In accordance with some embodiments of the present disclosure, the deposition apparatus may further include a signal detector comprising a plurality of probe pins in contact with contact pads of the plurality of sensors.

In accordance with some embodiments of the present disclosure, the signal detector may be disposed in the mask chuck, and the deposition mask may have a through hole or a recess through which the plurality of probe pins pass.

In accordance with some embodiments of the present disclosure, the signal detector may respectively detect capacitances between the measurement electrodes of the sensors and the deposition mask and measure, based on the detected capacitances, the gaps between the substrate and the deposition mask.

In accordance with some embodiments of the present disclosure, a plurality of spacers may be disposed on the deposition mask and face the measurement electrodes of the sensors, and the signal detector may respectively detect the capacitances between the measurement electrodes of the sensors and the spacers and measure, based on the detected capacitances, the gaps between the substrate and the deposition mask.

In accordance with some embodiments of the present disclosure, the substrate may include display cell regions, a scribe lane region disposed between the display cell regions, and an edge region. Each of the plurality of sensors may include a first contact electrode and a second contact electrode disposed on the scribe lane region, a first contact pad and a second contact pad disposed on the edge region, and a first wiring and a second wiring disposed on the scribe lane region wherein the first wiring connects the first contact electrode and the first contact pad, and the second wiring connects the second contact electrode and the second contact pad.

In accordance with some embodiments of the present disclosure, the deposition apparatus may further include a signal detector comprising a plurality of probe pins in contact with the first contact pads and the second contact pads of the plurality of sensors.

In accordance with some embodiments of the present disclosure, a plurality of spacers may be disposed on the deposition mask and face the first contact electrodes and the second contact electrodes, and the signal detector may detect whether or not the first contact electrodes and the second contact electrodes are in contact with the plurality of spacers and measure, based on detecting whether or not the first contact electrodes and the second contact electrodes are in contact with the spacers, the gaps between the substrate and the deposition mask.

In accordance with some embodiments of the present disclosure, the deposition mask may include mask cell regions, a grid region disposed between the mask cell regions, and an edge region. Each of the plurality of sensors may include a measurement electrode disposed on the grid region, a contact pad disposed on the edge region, and a wiring disposed on the grid region and connecting the measurement electrode and the contact pad.

In accordance with some embodiments of the present disclosure, the deposition apparatus may further include a signal detector comprising a plurality of probe pins in contact with contact pads of the plurality of sensors.

In accordance with some embodiments of the present disclosure, the signal detector may be disposed in the mask chuck. The deposition mask may have a sensor opening exposing the contact pads, and the plurality of probe pins may be brought into contact with the contact pads through the sensor opening.

In accordance with some embodiments of the present disclosure, the signal detector may respectively detect capacitances between measurement electrodes of the sensors and the substrate and measure, based on the detected capacitances, the gaps between the substrate and the deposition mask.

In accordance with some embodiments of the present disclosure, the substrate chuck driver may include a hexapod actuator providing a motion of six degrees of freedom in association with adjusting the position and the inclination of the substrate chuck.

In accordance with some embodiments of the present disclosure, the deposition apparatus may further include a plurality of gap sensors for measuring gaps between the substrate chuck and the mask chuck. The substrate chuck driver may adjust the inclination of the substrate chuck based on measurements of the gaps between the substrate chuck and the mask chuck as provided by the plurality of gap sensors in association with adjusting a parallelism between the substrate chuck and the mask chuck.

In accordance with some embodiments of the present disclosure, the deposition apparatus may further include a plurality of first gap sensors for measuring gaps between the substrate chuck and the mask chuck. The substrate chuck driver may adjust the position of the substrate chuck such that the gap between the substrate and the deposition mask becomes a first gap, and may then adjust the inclination of the substrate chuck based on measurements of the gaps between the substrate chuck and the mask chuck as provided by the plurality of first gap sensors in association with adjusting the parallelism between the substrate chuck and the mask chuck.

In accordance with some embodiments of the present disclosure, the deposition apparatus may further include a plurality of second gap sensors measuring the gaps between the substrate chuck and the mask chuck and having a resolution higher than a resolution of the plurality of first gap sensors. The substrate chuck driver may adjust the position of the substrate chuck such that the gap between the substrate and the deposition mask becomes a second gap smaller than the first gap, and may then adjust the inclination of the substrate chuck based on measurements of the gaps between the substrate chuck and the mask chuck as provided by the plurality of second gap sensors in association with adjusting the parallelism between the substrate chuck and the mask chuck.

In accordance with still another aspect of the present disclosure, an electronic device may include a display panel including a substrate and light emitting material layers formed on the substrate using a deposition apparatus. The deposition apparatus may include a deposition source providing a deposition material onto the substrate, a mask chuck disposed above the deposition source and supporting a deposition mask, a substrate chuck disposed above the mask chuck and supporting the substrate such that the substrate faces the deposition mask, and a substrate chuck driver adjusting a position and an inclination of the substrate chuck in association with positioning the substrate on the deposition mask and adjusting a parallelism between the substrate and the deposition mask. In such case, a plurality of sensors for measuring gaps between the substrate and the deposition mask may be disposed on the substrate or the deposition mask, and the substrate chuck driver may adjust the inclination of the substrate chuck based on measurements of the gaps between the substrate and the deposition mask as provided by the plurality of sensors.

In accordance with the embodiments of the present disclosure as described herein, sensors for measuring a gap may be disposed on the substrate or the deposition mask, and the gaps between the substrate and the deposition mask may be measured using the sensors. Further, the parallelism between the substrate and the deposition mask may be adjusted based on measurements of the gaps as provided by the sensors, such that the pixel position accuracy of deposition material layers formed on the substrate may be improved, and the color mixing phenomenon between sub-pixels may be reduced.

Other features and embodiments may be apparent from the following detailed description and the drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device illustrated in FIG. 3;

FIG. 5 is an equivalent circuit diagram illustrating an example of a first sub-pixel illustrated in FIG. 4;

FIG. 6 is a schematic plan view illustrating an example of a display panel illustrated in FIG. 3;

FIG. 7 is a schematic enlarged plan view illustrating an example of a display area illustrated in FIG. 6;

FIG. 8 is a schematic enlarged plan view illustrating another example of the display area illustrated in FIG. 6;

FIG. 9 is a schematic cross-sectional view illustrating an example of the display panel taken along line I1-I1′ illustrated in FIG. 7;

FIG. 10 is a schematic cross-sectional view illustrating another example of the display panel taken along line I1-I1′ illustrated in FIG. 7;

FIG. 11 is a schematic perspective view illustrating an example of a head mounted display;

FIG. 12 is a schematic exploded perspective view illustrating the head mounted display illustrated in FIG. 11;

FIG. 13 is a schematic perspective view illustrating another example of the head mounted display;

FIG. 14 is a schematic diagram illustrating a deposition apparatus according to an embodiment of the present disclosure;

FIG. 15 is a schematic bottom view illustrating a backplane substrate according to an embodiment of the present disclosure;

FIG. 16 is a schematic plan view illustrating a deposition mask according to an embodiment of the present disclosure;

FIG. 17 is a schematic enlarged plan view illustrating mask cell regions illustrated in FIG. 16;

FIG. 18 is a schematic enlarged cross-sectional view taken along line I2-I2′ illustrated in FIG. 17;

FIG. 19 is a schematic enlarged bottom view illustrating another example of sensors illustrated in FIG. 15;

FIG. 20 is a schematic plan view illustrating a mask chuck illustrated in FIG. 14;

FIG. 21 is a schematic cross-sectional view illustrating a substrate chuck and a mask chuck illustrated in FIG. 14;

FIG. 22 is a schematic cross-sectional view illustrating a signal detector illustrated in FIG. 21;

FIG. 23 is a schematic enlarged cross-sectional view illustrating a through opening of the deposition mask illustrated in FIG. 22;

FIG. 24 is a plan view illustrating a deposition mask according to another embodiment of the present disclosure;

FIG. 25 is a schematic plan view illustrating a deposition mask according to still another embodiment of the present disclosure;

FIG. 26 is a schematic enlarged cross-sectional view taken along line I3-I3′ illustrated in FIG. 25;

FIG. 27 is a flowchart illustrating a deposition method according to still another embodiment of the present disclosure;

FIG. 28 is a flowchart illustrating step S200 illustrated in FIG. 27; and

FIG. 29 is a flowchart illustrating step S240 illustrated in FIG. 28.

### DETAILED DESCRIPTION

The invention will now be described more fully hereinafter with reference to the accompanying drawings, in which various embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the invention. Similarly, the second element could also be termed the first element.

The terminology used herein is for the purpose of describing particular embodiments and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

The display device according to an embodiment of the present disclosure can be applied to various electronic devices. The electronic device according to embodiments of the present disclosure includes the display device described herein, and may further include modules or devices having additional functions in addition to the display device.

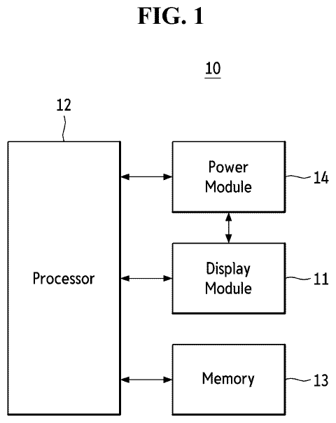

FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information supportive of the operation of the processor 12 or the display module 11. In an example in which the processor 12 executes an application stored in the memory 13, an image data signal and/or an input control signal is transmitted to the display module 11, and the display module 11 can process the received signal and output image information through a display screen.

The power module 14 may include a power supply module such as, for example, a power adapter or a battery, and a power conversion module that converts the power supplied by the power supply module to generate power supportive of the operation of the electronic device 10.

At least one of the components of the electronic device 10 according to embodiments of the present disclosure may be included in the display device 20 according to the embodiments of the present disclosure. In some aspects, some modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

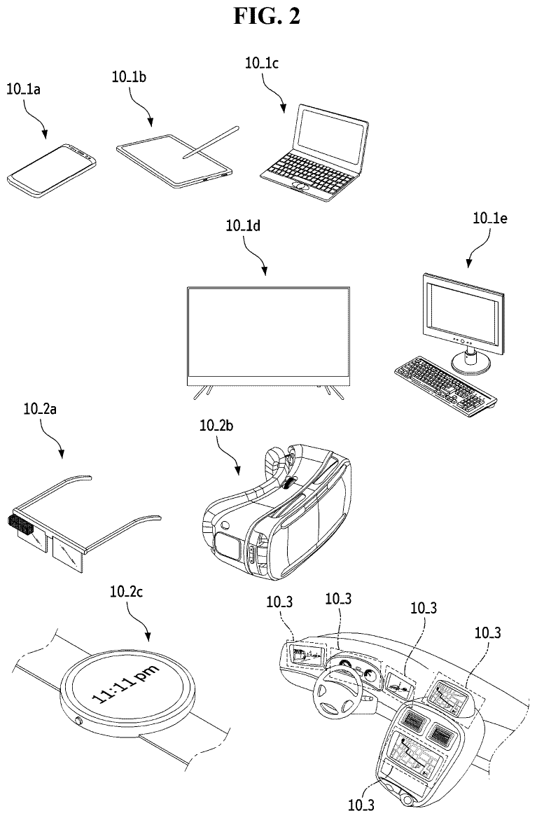

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as, for example, a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as, for example, a CID (Center Information Display) and a room mirror display arranged on a dashboard, center fascia, and dashboard of an automobile.

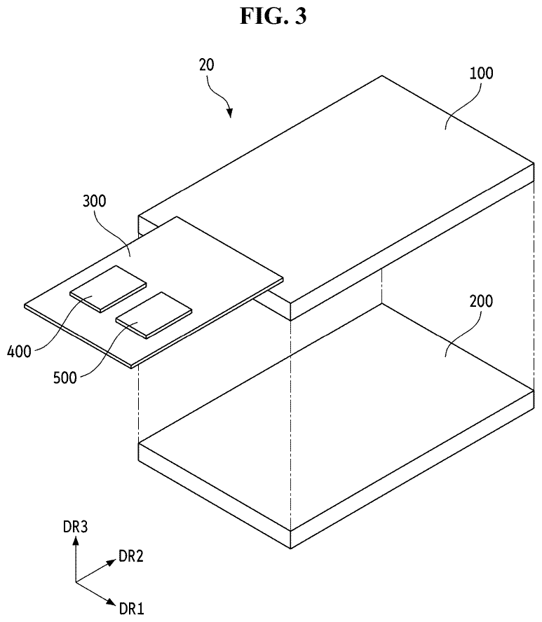

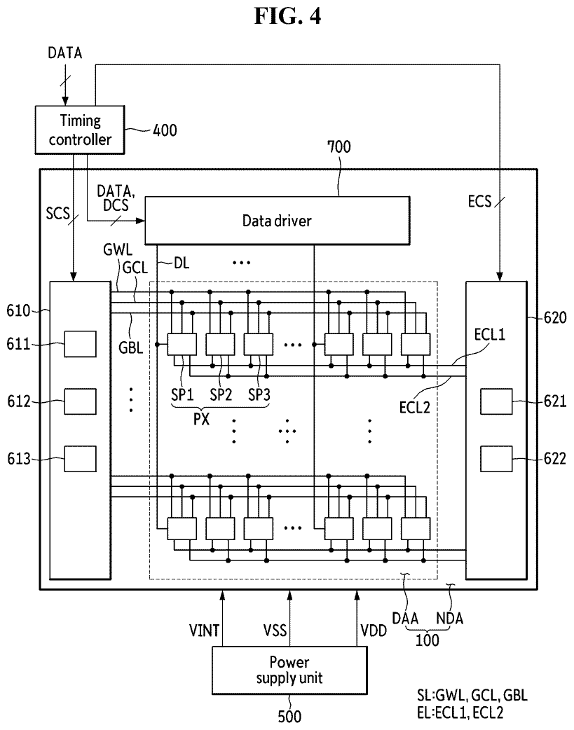

FIG. 3 is an exploded perspective view illustrating a display device according to an embodiment of the present disclosure. FIG. 4 is a block diagram illustrating the display device illustrated in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. For example, the display device 20 according to an embodiment may be applied to portable electronic devices 10 such as, for example, a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as, for example, a television, a laptop, a monitor, a billboard, or an Internet-of-Things (IoT) terminal, and the like. The display device 20 according to an embodiment may be applied to electronic devices 10 such as, for example, a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as illustrated in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

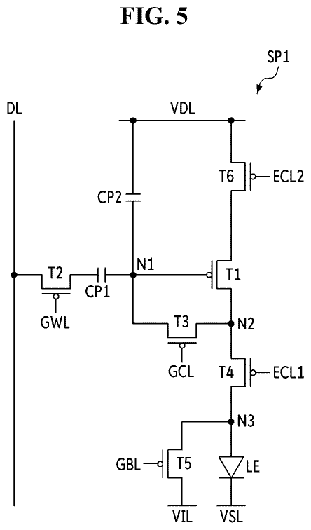

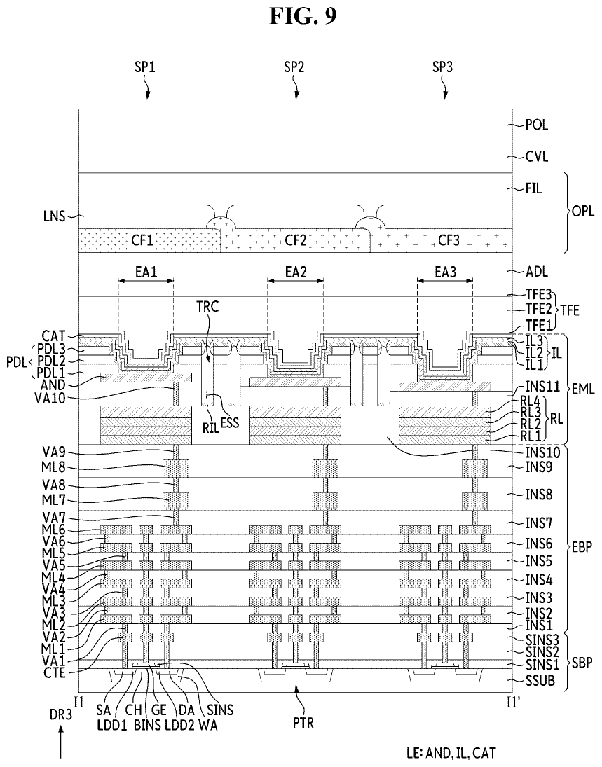

The plurality of pixels PX may include a plurality of sub-pixels SP1, SP2, and SP3. The plurality of sub-pixels SP1, SP2, and SP3 may include a plurality of pixel transistors as illustrated in FIG. 5, and the plurality of pixel transistors may be formed by a semiconductor process and disposed on a semiconductor substrate SSUB (see FIG. 9). For example, the plurality of pixel transistors of the data driver 700 may be formed of complementary metal oxide semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. For example, the plurality of scan transistors and the plurality of light emitting transistors may be formed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see FIG. 9) through a semiconductor process. For example, the plurality of data transistors may be formed of CMOS, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on a surface of the display panel 100, for example, on the rear surface of the display panel 100. The heat dissipation layer 200 serves to dissipate heat generated from the display panel 100. The heat dissipation layer 200 may include a metal layer having high thermal conductivity, such as, for example, graphite, silver (Ag), copper (Cu), or aluminum (Al).

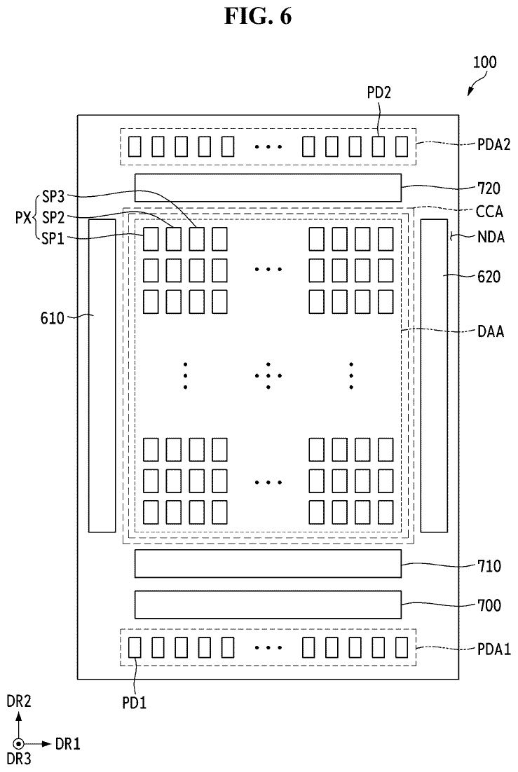

The circuit board 300 may be electrically connected to a plurality of first pads PD1 (see FIG. 6) of a first pad portion PDA1 (see FIG. 6) of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. For example, the plurality of timing transistors and the plurality of power transistors may be formed of CMOS, but embodiments of the present disclosure are not limited thereto. Each of the timing control circuit 400 and the power supply circuit 500 may be disposed between the data driver 700 and the first pad portion PDA1 (se FIG. 6).

FIG. 5 is an equivalent circuit diagram illustrating an example of a first sub-pixel illustrated in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode of the first transistor T1 according to a voltage applied to the gate electrode of the first transistor T1.

A second transistor T2 may be disposed between one electrode of the first capacitor CP1 and the data line DL. The second transistor T2 is turned on by the write scan signal of the write scan line GWL in association with connecting the one electrode of the first capacitor CP1 to the data line DL. Accordingly, the data voltage of the data line DL may be applied to the one electrode of the first capacitor CP1.

A third transistor T3 may be disposed between the first node N1 and the second node N2. The third transistor T3 is turned on by the control scan signal of the control scan line GCL in association with connecting the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 in association with connecting the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL in association with connecting the third node N3 to the third driving voltage line VIL. Accordingly, the third driving voltage VINT of the third driving voltage line VIL may be applied to the first electrode of the light emitting element LE.

The sixth transistor T6 may be disposed between the source electrode of the first transistor T1 and the second driving voltage line VDL. The sixth transistor T6 is turned on by the second emission control signal of the second emission control line ECL2 in association with connecting the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that illustrated in FIG. 5. For example, the number of transistors and the number of capacitors of the first sub-pixel SP1 are not limited to those illustrated in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 is not repeated in the present disclosure.

FIG. 6 is a schematic plan view illustrating an example of a display panel illustrated in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. However, embodiments of the present disclosure are not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board formed of a rigid material or a flexible printed circuit board formed of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. For example, the cathode connection part CCA may be disposed outside at least on one side among the left side, the right side, the upper side, and the lower side of the display area DAA. Alternatively, the cathode connection part CCA may be disposed to surround the display area DAA as illustrated in FIG. 6 in order to minimize a deviation in the first driving voltage VSS caused by voltage drop (IR drop) or voltage rise (IR rising) of the second electrode CAT in the display area DAA.

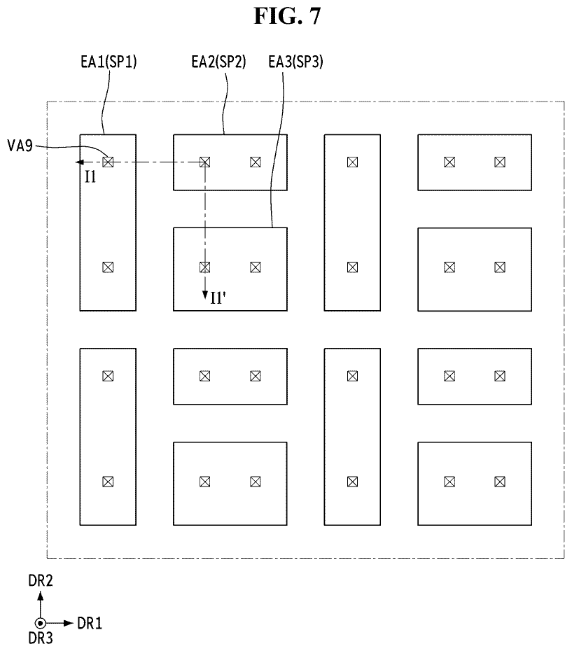

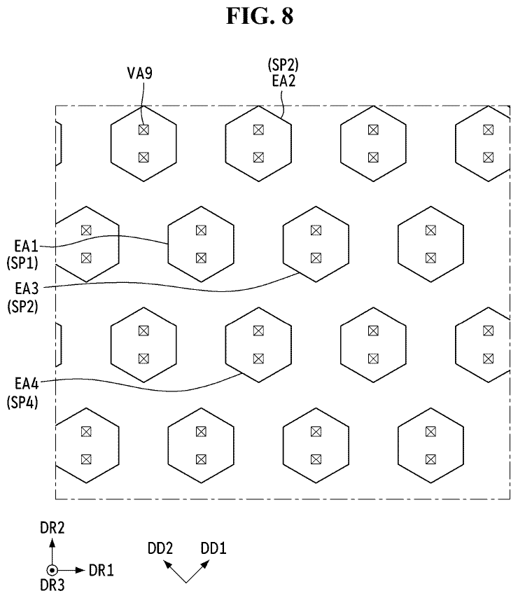

FIG. 7 is a schematic enlarged plan view illustrating an example of a display area illustrated in FIG. 6. FIG. 8 is a schematic enlarged plan view illustrating another example of the display area illustrated in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as illustrated in FIGS. 7 and 8, but embodiments of the present disclosure are not limited thereto. The first emission area EA1, the second emission area EA2, and the third emission area EA3 may have a polygonal shape other than a quadrangle or hexagon, a circular shape, an elliptical shape, or an atypical shape in plan view.

As illustrated in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In some aspects, the second emission area EA2 and the third emission area EA3 may be adjacent to each other in the second direction DR2. The area of the first emission area EA1, the area of the second emission area EA2, and the area of the third emission area EA3 may be different.

Alternatively, as illustrated in FIG. 8, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. In some aspects, the first emission area EA1 and the second emission area EA2 may be adjacent in a first diagonal direction DD1, and the second emission area EA2 and the third emission area EA3 may be adjacent in a second diagonal direction DD2. In some aspects, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

As illustrated in FIG. 7, each of the plurality of pixels PX may include three emission areas EA1, EA2, and EA3, or may include four emission areas EA1, EA2, EA3, and EA4 as illustrated in FIG. 8. In this case, the fourth emission area EA4 may emit the same second light as the second emission area EA2, but embodiments of the present disclosure are not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as illustrated in FIG. 8, or a hexagonal structure in which the emission areas are arranged in a hexagonal shape.

FIG. 9 is a schematic cross-sectional view illustrating an example of the display panel taken along line I1-I1′ illustrated in FIG. 7.

Referring to FIG. 9, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but embodiments of the present disclosure are not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 illustrated in FIG. 5.

For example, the first to sixth transistors T1 to T6 are formed in the semiconductor backplane SBP, and the connection of the first to sixth transistors T1 to T6 and the first and second capacitors C1 and C2 is accomplished through the first to eighth conductive layers ML1 to ML8. In some aspects, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be formed of substantially the same material. First to eighth interlayer insulating films INS1 to INS8 may be formed of a silicon oxide (SiOx)-based inorganic layer, but embodiments of the present disclosure are not limited thereto.

A ninth interlayer insulating film INS9 may be disposed on the eighth interlayer insulating film INS8 and the eighth conductive layer ML8. The ninth interlayer insulating film INS9 may be formed of a silicon oxide (SiOx)-based inorganic film, but embodiments of the present disclosure are not limited thereto.

Each of the ninth vias VA9 may penetrate the ninth interlayer insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. For example, each of the reflective electrodes RL may include the first to fourth reflective electrodes RL1, RL2, RL3, and RL4 as illustrated in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may contain titanium nitride (TIN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may be formed of a silicon oxide (SiOx)-based inorganic film, but embodiments of the present disclosure are not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as illustrated in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In some aspects, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film. Alternatively, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 9 illustrates that two trenches TRC are disposed between the neighboring sub-pixels SP1, SP2, and SP3, embodiments of the present disclosure are not limited thereto.

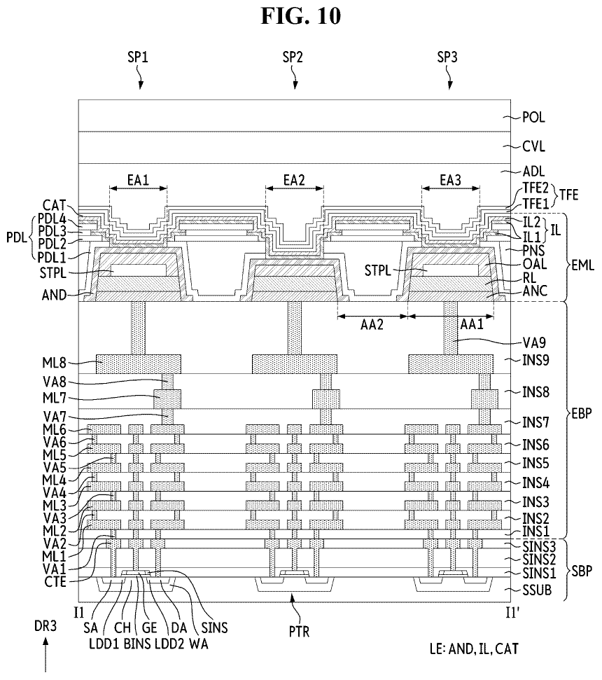

The light emitting stack IL may include a plurality of stack layers IL1, IL2, and IL3. FIG. 9 illustrates that the light emitting stack IL has a three-tandem structure including a first stack layer IL1, a second stack layer IL2, and a third stack layer IL3, but embodiments of the present disclosure are not limited thereto. For example, the light emitting stack IL may have a two-tandem structure including two stack layers as illustrated in FIG. 10.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed such that the third stack layer IL3 covers the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In some aspects, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be disposed on the pixel defining film PDL.

In some aspects, FIG. 9 illustrates that the light emitting stack IL that emits light is disposed in the first emission area EA1, the second emission area EA2, and the third emission area EA3, but embodiments of the present disclosure are not limited thereto. For example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. In an example in which the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may be formed of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In some aspects, the encapsulation layer TFE may include at least one organic film TFE2 to protect the display element layer EML from foreign substances such as, for example, dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as, for example, acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In some aspects, the adhesive layer ADL may be a transparent adhesive member such as, for example, a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as, for example, acrylic resin, epoxy resin, phenolic resin, polyamide resin, or polyimide resin.

The cover layer CVL may be disposed on the filling layer FIL. The cover layer CVL may be a glass substrate or a polymer resin. In an example in which the cover layer CVL is a glass substrate, the cover layer CVL may be attached onto the filling layer FIL. In this case, the filling layer FIL may serve to bond the cover layer CVL. In an example in which the cover layer CVL is a glass substrate, the cover layer CVL may serve as an encapsulation substrate. In an example in which the cover layer CVL is a polymer resin, the cover layer CVL may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a N4 plate (quarter-wave plate), but embodiments of the present disclosure are not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1′ illustrated in FIG. 7.

The embodiment of FIG. 10 differs from the embodiment of FIG. 9 in that the first electrode AND of each of the light emitting elements LE is in contact with and electrically connected to the side surface of a connection electrode ANC connected to the eighth conductive layer ML8. The embodiment of FIG. 10 also differs from the embodiment of FIG. 9 in that the trench TRC is omitted, and instead, the third pixel defining film PDL3 and a fourth pixel defining film PDL4 have an eave-shaped or mushroom-shaped cross-sectional structure. In the embodiment of FIG. 10, redundant description of parts already described in the embodiment of FIG. 9 will be omitted.

Referring to FIG. 10, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed of a silicon oxide (SiOx)-based inorganic film, but embodiments of the present disclosure are not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, for example, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and the wavelength and resonance distance of light emitted from the second stack layer IL2 of the light emitting stack IL.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary layer OAL are sequentially stacked, the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

Alternatively, the thickness of the first portion AA1 of the ninth interlayer insulating film INS9 may be greater than the thickness of the second portion AA2 of the ninth interlayer insulating film INS9. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In contrast, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may be formed of a silicon nitride (SiNx)-based inorganic film, whereas the second pixel defining film PDL2, the fourth pixel defining film PDL4, and the planarization film PNS may be formed of a silicon oxide (SiOx)-based inorganic film. The first pixel defining film PDL1 is formed of a material different from a material of the planarization film PNS, and thus may serve as a stopper in a chemical mechanical polishing process for the planarization film PNS.

When the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an caves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights. In an example in which the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the caves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, embodiments of the present disclosure may prevent a leakage current from flowing through the first hole transport layer of the first stack layer IL1, the second hole transport layer of the second stack layer IL2, and the charge generation layer between the adjacent emission areas EA1, EA2, and EA3. Accordingly, embodiments of the present disclosure may prevent the light emitting stack IL in the adjacent emission areas EA1, EA2, and EA3 from emitting light other than the originally intended light due to the influence of the above current.

Although FIG. 10 illustrates a two-tandem structure in which the light emitting stack IL includes two stack layers IL1 and IL2, embodiments of the present disclosure are not limited thereto. For example, the light emitting stack IL may have a three-tandem structure including three stack layers as illustrated in FIG. 9. In this case, the light emitting stack IL may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as illustrated in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but embodiments of the present disclosure are not limited thereto.

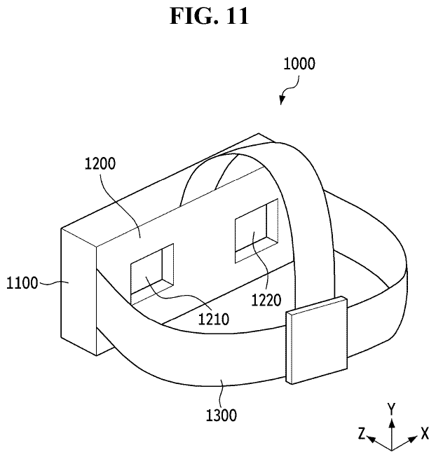

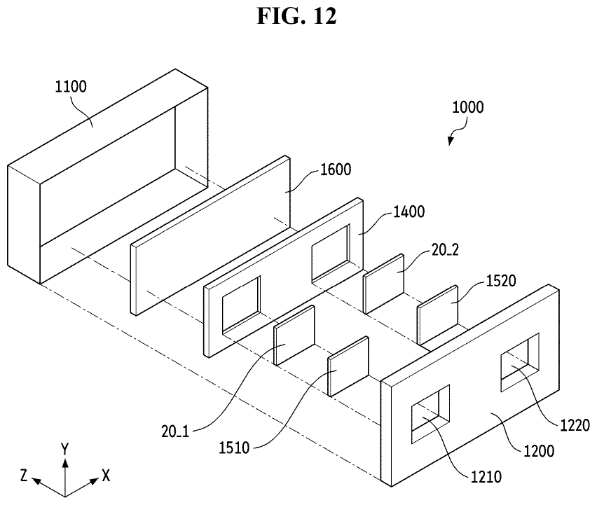

FIG. 11 is a schematic perspective view illustrating one example of a head mounted display. FIG. 12 is a schematic exploded perspective view illustrating the head mounted display illustrated in FIG. 11.

Referring to FIGS. 11 and 12, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA, and transmit the digital video data DATA to the first display device 20_1 and the second display device 20_2 through the connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. Alternatively, the control circuit board 1600 may transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed such that the housing cover 1200 covers an open surface of the display device housing 1100. The housing cover 1200 may include the first eyepiece 1210 at which the user's left eye is located and the second eyepiece 1220 at which the user's right eye is located. FIGS. 11 and 12 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

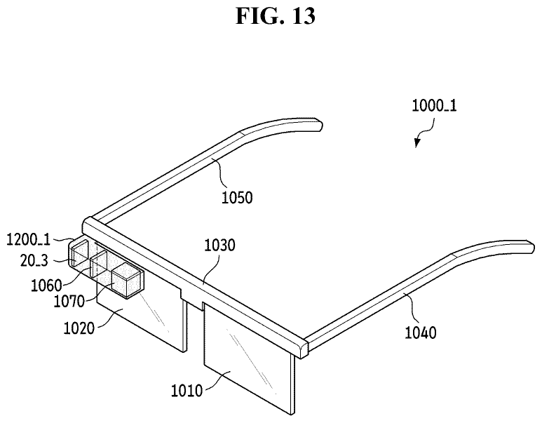

The head mounted band 1300 serves to secure the display device housing 1100 to the user's head such that the first eyepiece 1210 and the second eyepiece 1220 of the housing cover 1200 remain located on the user's left and right eyes, respectively. In an example in which the housing cover 1200 is implemented to be lightweight and compact, the head mounted display 1000 may be provided with, as illustrated in FIG. 13, an eyeglass frame instead of the head mounted band 1300.

FIG. 13 is a schematic perspective view illustrating another example of a head mounted display.

Referring to FIG. 13, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path of the image is changed by the optical path changing member 1070. As a result, the user may view an augmented reality image, through the right eye, in which a virtual image displayed on the display device 20_3 and a real image seen through the right eye lens 1020 are combined.

FIG. 13 illustrates that the display device housing 1200_1 is disposed at the right end of the support frame 1030, but embodiments of the present disclosure are not limited thereto. For example, the display device housing 1200_1 may be disposed at the left end of the support frame 1030, and in this case, the image of the display device 20_3 may be provided to the user's left eye. Alternatively, the display device housing 1200_1 may be disposed at both the left and right ends of the support frame 1030, and in this case, the user may view the image displayed on the display device 20_3 through both the left and right eyes.

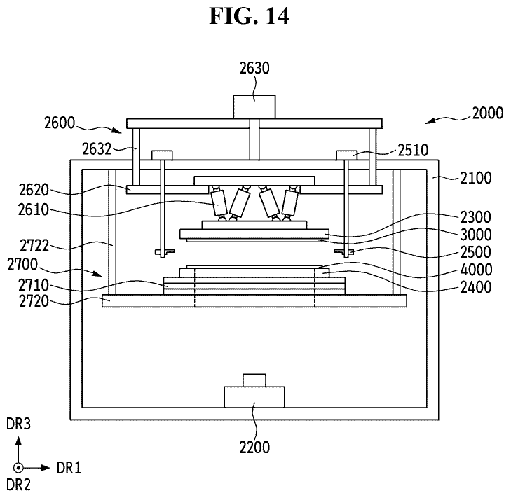

FIG. 14 is a schematic diagram illustrating a deposition apparatus according to an embodiment of the present disclosure.

Referring to FIG. 14, a deposition apparatus 2000 according to an embodiment of the present disclosure may be used for forming deposition material layers on a substrate 3000. For example, the deposition apparatus 2000 according to an embodiment of the present disclosure may be used for forming light emitting material layers on a backplane substrate 3000 for manufacturing a display panel. In this case, as illustrated in FIGS. 9 and 10, the semiconductor backplane SBP and the light emitting element backplane EBP may be arranged on the backplane substrate 3000, and the electrode patterns AND such as, for example, anode electrodes and the pixel defining film PDL having openings exposing the electrode patterns AND may be disposed on the light emitting element backplane EBP.

The deposition apparatus 2000 according to an embodiment of the present disclosure may be used for forming light emitting material layers respectively on the electrode patterns AND. For example, the deposition apparatus 2000 according to an embodiment of the present disclosure may be used for forming first light emitting material layers for emitting first light having a blue wavelength band on the electrode patterns AND respectively arranged in the first emission areas EA1, second light emitting material layers for emitting second light having a green wavelength band on the electrode patterns AND respectively arranged in the second emission areas EA2, and third light emitting material layers for emitting third light having a blue wavelength band on the electrode patterns AND respectively arranged in the third emission areas EA3.

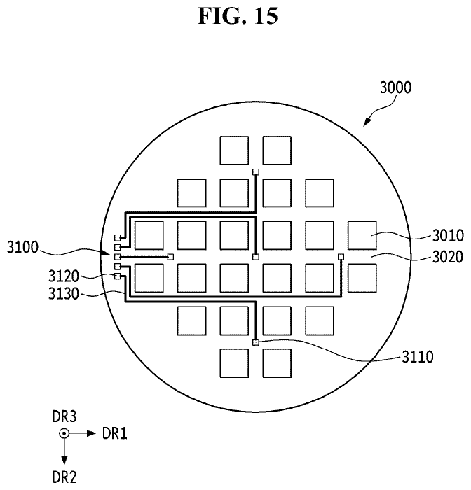

FIG. 15 is a schematic bottom view illustrating a backplane substrate according to an embodiment of the present disclosure.

Referring to FIG. 15, the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 intersecting the first direction DR1, and the display cell regions 3010 may be respectively individualized into a plurality of display panels 100 by a dicing process after the display manufacturing process is completed. For example, the first direction DR1 may be a first horizontal direction, and the second direction DR2 may be a second horizontal direction perpendicular to the first direction DR1. In this case, the first direction DR1 may be an X-axis direction, and the second direction DR2 may be a Y-axis direction.

Although not illustrated in detail, each of the display cell regions 3010 may include the semiconductor backplane SBP and the light emitting element backplane EBP disposed on the semiconductor backplane SBP, and the plurality of electrode patterns AND may be disposed on the light emitting element backplane EBP. Further, the pixel defining film PDL may be disposed on the display cell regions 3010 and the scribe lane region 3020, and the pixel defining film PDL may have a plurality of openings exposing the electrode patterns AND.

According to one embodiment of the present disclosure, a plurality of sensors 3100 for measuring gaps between the backplane substrate 3000 and a deposition mask 4000 in a deposition process for forming deposition material layers may be formed on the backplane substrate 3000. For example, each of the plurality of sensors 3100 may include a measurement electrode 3110, a contact pad 3120, and a wiring 3130, and may be arranged on the pixel defining film PDL. Specifically, the plurality of measurement electrodes 3110 may be respectively disposed on the scribe lane region 3020 at preset measuring points, and the plurality of contact pads 3120 may be arranged on the edge portion of the backplane substrate 3000. The plurality of wirings 3130 may connect the measurement electrodes 3110 and the contact pads 3120 and may be disposed on the scribe lane region 3020. As illustrated, five sensors 3100 are arranged on the backplane substrate 3000, but the positions and number of the sensors 3100 may be variously changed and the scope of the present disclosure is not limited thereby.

According to one embodiment of the present disclosure, the measurement electrodes 3110, the contact pads 3120, and the wirings 3130 may be formed of a conductive material, e.g., metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

For example, after a conductive material layer is formed on the pixel defining film PDL, the conductive material layer may be patterned to simultaneously form the measurement electrodes 3110, the contact pads 3120, and the wirings 3130 on the pixel defining film PDL. Specifically, although not illustrated, after a photoresist pattern (not illustrated) that exposes portions other than portions where the measurement electrodes 3110, the contact pads 3120, and the wirings 3130 are to be formed is formed on the conductive material layer, an anisotropic etching process using the photoresist pattern as an etching mask may performed to form the measurement electrodes 3110, the contact pads 3120, and the wirings 3130 on the pixel defining film PDL. In another example, the measurement electrodes 3110, the contact pads 3120, and the wirings 3130 may be formed by a damascene process.

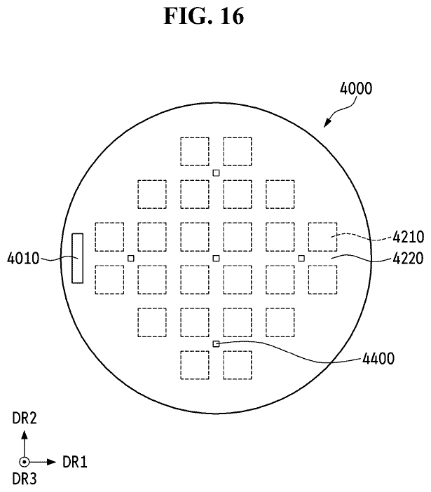

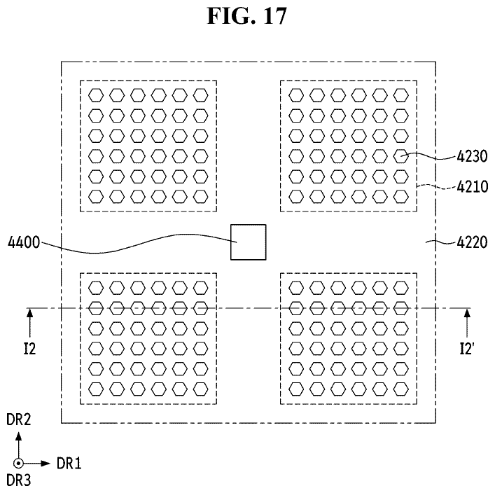

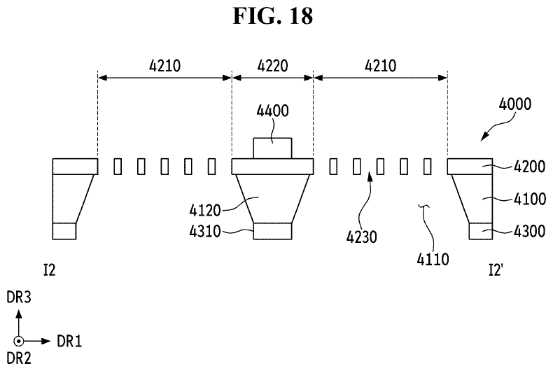

FIG. 16 is a schematic plan view illustrating a deposition mask according to an embodiment of the present disclosure. FIG. 17 is a schematic enlarged plan view illustrating the mask cell regions illustrated in FIG. 16, and FIG. 18 is a schematic enlarged cross-sectional view taken along line I2-I2′ illustrated in FIG. 17.

Referring to FIGS. 16 to 18, the deposition mask 4000 may include mask cell regions 4210 respectively corresponding to the display cell regions 3010 of the backplane substrate 3000. Each of the mask cell regions 4210 may have a plurality of pixel openings 4230 exposing the electrode patterns AND of the backplane substrate 3000 in a deposition process.

For example, the deposition mask 4000 may include a mask frame 4100 and a membrane 4200 disposed on the mask frame 4100. In this case, the membrane 4200 may include a plurality of mask cell regions 4210 and a grid region 4220 disposed between the mask cell regions 4210, and each of the mask cell regions 4210 may have the plurality of pixel openings 4230. The mask frame 4100 may have cell openings 4110, and may include a rib region 4120 defining the cell openings 4110. In this case, the mask cell regions 4210 may be respectively arranged on the cell openings 4110, and the grid region 4220 may be disposed on the rib region 4120. Further, the mask cell regions 4210 may be exposed through the cell openings 4110, and the pixel openings 4230 may be connected to the cell openings 4110 while penetrating the mask cell regions 4210.

The mask cell regions 4210 may be arranged in a matrix form along the first direction DR1 and the second direction DR2, as illustrated in FIG. 16. For example, the mask cell regions 4210 may be arranged in a matrix form along the first horizontal direction DR1 and the second horizontal direction DR2 perpendicular to the first horizontal direction DR1, and may be arranged to respectively correspond to the display cell regions 3010 of the backplane substrate 3000.

The membrane 4200 may be disposed on the front surface of the mask frame 4100, and a rear inorganic film 4300 may be disposed on the rear surface of the mask frame 4100. The membrane 4200 and the rear inorganic film 4300 may be formed of the same material. For example, the membrane 4200 and the rear inorganic film 4300 may be formed of an inorganic material such as, for example, silicon nitride (SiNx), and may be formed to have a thickness of about 0.5 μm to about 3 μm by a thermal chemical vapor deposition (TCVD) process. That is, a front inorganic film and the rear inorganic film 4300 may be simultaneously formed on the front surface and the rear surface of the mask frame 4100 by the TCVD process, respectively, and the front inorganic film may be used as the membrane 4200.

A single crystal silicon substrate may be used as the mask frame 4100, and the pixel openings 4230 may be formed by forming the membrane 4200 on the mask frame 4100 and then patterning the membrane 4200. For example, the pixel openings 4230 may be formed by forming a photoresist pattern (not illustrated) that exposes portions where the pixel openings 4230 are to be formed on the membrane 4200, and then performing an anisotropic etching process using the photoresist pattern as an etching mask until the mask frame 4100 is exposed.

The rear inorganic film 4300 may have rear openings 4310 communicating with the cell openings 4110, and may function as an etching mask in an etching process for forming the cell openings 4110. For example, the rear openings 4310 may be formed by forming a photoresist pattern (not illustrated) that exposes portions where the rear openings 4310 are to be formed on the rear inorganic film 4300, and then performing an anisotropic etching process using the photoresist pattern as an etching mask until the rear surface of the mask frame 4100 is exposed.

The cell openings 4110 may be formed to expose the mask cell regions 4210 of the membrane 4200 through an anisotropic etching process using the rear inorganic film 4300 as an etching mask. For example, the cell openings 4110 may be formed through a wet etching process using tetramethylammonium hydroxide (TMAH) or potassium hydroxide (KOH). In this case, the <100> crystal direction of the single crystal silicon substrate used as the mask frame 4100 may be the third direction DR3, such that the cell openings 4110 may be formed to have a width that gradually decreases toward the membrane 4200, i.e., in the third direction DR3, by the wet etching process. For example, each of the inner surfaces of the cell openings 4110 may be formed to have an inclination of about 54.74°.

According to one embodiment of the present disclosure, the deposition mask 4000 may include spacers 4400 respectively corresponding to the sensors 3100 on the backplane substrate 3000. In particular, the spacers 4400 may be arranged on the grid region 4220 of the deposition mask 4000 to respectively correspond to the measurement electrodes 3110. In an example in which the backplane substrate 3000 is positioned on the deposition mask 4000 to perform a deposition process, the measurement electrodes 3110 and the spacers 4400 face each other, and the gaps between the measurement electrodes 3110 and the spacers 4400 may be measured according to the capacitance between the measurement electrodes 3110 and the spacers 4400. In this case, each of the spacers 4400 may be used as a sensor dog (or detection target) for measuring the gap between the backplane substrate 3000 and the deposition mask 4000, and the gaps between the backplane substrate 3000 and the deposition mask 4000 may be calculated from the gaps between the measurement electrodes 3110 and the spacers 4400.

The spacers 4400 may be formed of a dielectric material or a conductive material. For example, the spacers 4400 may be formed of a dielectric material such as, for example, silicon oxide (SiOx), silicon nitride (SiNx), silicon oxynitride (SiON), aluminum oxide (AlOx), hafnium oxide (HfOx), zirconium oxide (ZrOx), or the like. In another example, the spacers 4400 may be formed of metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

The spacers 4400 may be formed on the membrane 4200 after the membrane 4200 is formed. In this case, the pixel openings 4230 may be formed after the spacers 4400 are formed. In particular, the spacers 4400 may be formed on the grid region 4220 of the membrane 4200 to correspond to the measurement electrodes 3110 on the backplane substrate 3000. For example, after a dielectric material layer or a conductive material layer is formed on the membrane 4200, the spacers 4400 may be formed on the membrane 4200 by patterning the dielectric material layer or the conductive material layer. Specifically, although not illustrated, after a photoresist pattern (not illustrated) that exposes portions other than portions where the spacers 4400 are to be formed is formed on the dielectric material layer or the conductive material layer, an anisotropic etching process using the photoresist pattern as an etching mask may be performed until the membrane 4200 is exposed to form the spacers 4400 on the membrane 4200.

According to another embodiment of the present disclosure, the spacers 4400 may be omitted in the deposition mask 4000. In this case, in the deposition process, the measurement electrodes 3110 may face the membrane 4200 of the deposition mask 4000, and the gaps between the measurement electrodes 3110 and the membrane 4200 may be measured according to the capacitance between the measurement electrodes 3110 and the membrane 4200.

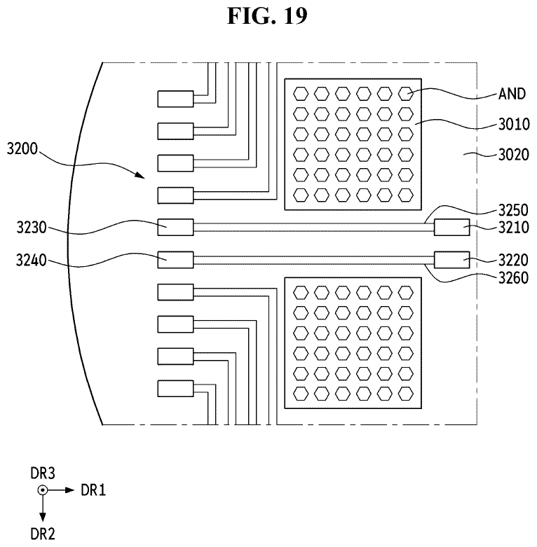

FIG. 19 is a schematic enlarged bottom view illustrating another example of the sensors illustrated in FIG. 15.

Referring to FIG. 19, a plurality of sensors 3200 may be arranged on the backplane substrate 3000. Each of the sensors 3200 may include a first contact electrode 3210, a second contact electrode 3220, a first contact pad 3230, a second contact pad 3240, a first wiring 3250, and a second wiring 3260. The first and second contact electrodes 3210 and 3220 may be arranged on the scribe lane region 3020, and the first and second contact pads 3230 and 3240 may be arranged on the edge portion of the backplane substrate 3000. The first and second wirings 3250 and 3260 may connect the first and second contact electrodes 3210 and 3220 and the first and second contact pads 3230 and 3240, and may be disposed on the scribe lane region 3020.

The first and second contact electrodes 3210 and 3220, the first and second contact pads 3230 and 3240, and the first and second wirings 3250 and 3260 may be formed of a conductive material, e.g., metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

For example, after a conductive material layer is formed on the pixel defining film PDL, the conductive material layer may be pattered to form the first and second contact electrodes 3210 and 3220, the first and second contact pads 3230 and 3240, and the first and second wirings 3250 and 3260 on the pixel defining film PDL. Specifically, although not illustrated, a photoresist pattern (not illustrated) that exposes portions where the first and second contact electrodes 3210 and 3220, the first and second contact pads 3230 and 3240, and the first and second wirings 3250 and 3260 are to be formed is formed on the conductive material layer, an anisotropic etching process using the photoresist pattern as an etching mask may be performed to form the first and second contact electrodes 3210 and 3220, the first and second contact pads 3230 and 3240, and the first and second wirings 3250 and 3260 on the pixel defining film PDL. In another example, the first and second contact electrodes 3210 and 3220, the first and second contact pads 3230 and 3240, and the first and second wirings 3250 and 3260 may be formed by a damascene process.

When each of the sensors 3200 includes the first and second contact electrodes 3210 and 3220 as described herein, the spacers 4400 of the deposition mask 4000 may be formed of a conductive material. In particular, when the backplane substrate 3000 is positioned on the deposition mask 4000, the first and second contact electrodes 3210 and 3220 may be in contact with the spacer 4400 corresponding to the first and second contact electrodes 3210 and 3220, and the first contact electrode 3210 and the second contact electrode 3220 may be electrically connected through the corresponding spacer 4400. In particular, when the first contact electrode 3210 and the second contact electrode 3220 are electrically connected, it may be determined that the first and second contact electrodes 3210 and 3220 and the spacer 4400 are in contact with each other at the corresponding point(s) of contact between the first and second contact electrodes 3210 and 3220 and the spacer 4400, and when the first contact electrode 3210 and the second contact electrode 3220 are not electrically connected, it may be determined that the first and second contact electrodes 3210 and 3220 and the spacer 4400 are not in contact with each other at the corresponding point(s) of contact between the first and second contact electrodes 3210 and 3220 and the spacer 4400. As a result, the gaps between the backplane substrate 3000 and the deposition mask 4000 may be measured depending on whether the first contact electrode 3210 and the second contact electrode 3220 are electrically connected at the plurality of measuring points.

Referring back to FIG. 14, the deposition apparatus 2000 according to an embodiment of the present disclosure may include the deposition source 2200 for providing a deposition material on the backplane substrate 3000, a substrate chuck 2300 for supporting the backplane substrate 3000 such that the backplane substrate 3000 faces the deposition source 2200, and a mask chuck 2400 disposed between the deposition source 2200 and the substrate chuck 2300 and supporting the deposition mask 4000 such that the deposition mask 4000 faces the backplane substrate 3000.

The deposition source 2200, the substrate chuck 2300, and the mask chuck 2400 may be disposed in a process chamber 2100. The process chamber 2100 may have an internal space, and a deposition process for forming a deposition material layer on the backplane substrate 3000 may be performed in the internal space of the process chamber 2100. The process chamber 2100 may be connected to a vacuum pump (not illustrated), and a vacuum atmosphere may be created in the internal space of the process chamber 2100 by the vacuum pump. An opening (not illustrated) for loading/unloading of the backplane substrate 3000 and the deposition mask 4000 may be provided on one wall of the process chamber 2100, and the opening may be opened and closed by a gate valve (not illustrated).

The deposition source 2200 may be disposed in the process chamber 2100, and a deposition material may be stored in the deposition source 2200. The deposition source 2200 may evaporate a deposition material such as, for example, an organic material, an inorganic material, a conductive material, or the like, and the evaporated deposition material may be deposited on the electrode patterns AND of the backplane substrate 3000 through the pixel openings 4230 of the deposition mask 4000. For example, the deposition source 2200 may evaporate an organic material for forming light emitting material layers on the backplane substrate 3000, and may be provided with a heater (not illustrated) for evaporating the organic material. The evaporated deposition material may be deposited on the electrode patterns AND of the backplane substrate 3000 through the pixel openings 4230 of the deposition mask 4000. As illustrated in FIG. 14, the deposition source 2200 may be disposed on the central portion of the bottom surface of the process chamber 2100, but the deposition source 2200 may be configured to move horizontally by a separate driver (not illustrated).

The substrate chuck 2300 may be disposed above the deposition source 2200 and may support the backplane substrate 3000 such that the backplane substrate 3000 faces the deposition source 2200. For example, the substrate chuck 2300 may be an electrostatic chuck that holds the rear surface of the backplane substrate 3000 using an electrostatic force. Specifically, the electrode patterns AND, the pixel defining film PDL, and the sensors 3100 may be disposed on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2500 for loading the backplane substrate 3000 onto the substrate chuck 2300 may be disposed in the process chamber 2100. The lift fingers 2500 may be disposed around the substrate chuck 2300 and the mask chuck 2400, and may be respectively moved vertically by finger drivers 2510. For example, three or four lift fingers 2500 may be disposed around the substrate chuck 2300 and the mask chuck 2400. The backplane substrate 3000 may be loaded into the process chamber 2100 by a transfer robot (not illustrated), and may be transferred from the transfer robot onto the lift fingers 2500 under the substrate chuck 2300. In this case, the rear surface of the backplane substrate 3000 may face the bottom surface of the substrate chuck 2300, and the lift fingers 2500 may support the front edge portions of the backplane substrate 3000. The finger drivers 2510 may raise the lift fingers 2500 such that the backplane substrate 3000 becomes adjacent to the bottom surface of the substrate chuck 2300 and, then, the rear surface of the backplane substrate 3000 may be held on the bottom surface of the substrate chuck 2300 by an electrostatic force.

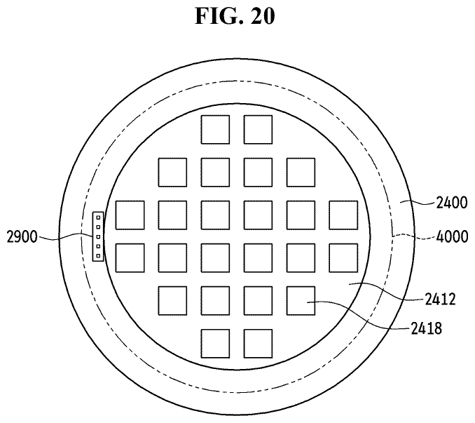

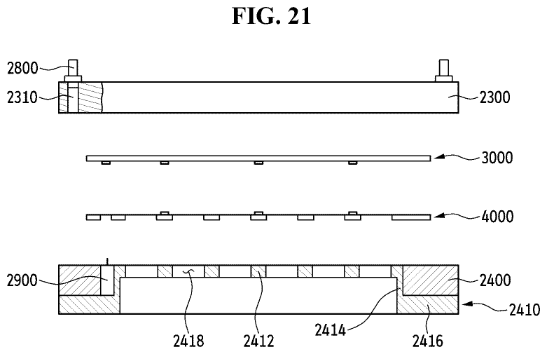

FIG. 20 is a schematic plan view illustrating the mask chuck illustrated in FIG. 14. FIG. 21 is a schematic cross-sectional view illustrating the substrate chuck and mask chuck illustrated in FIG. 14.

Referring to FIGS. 20 and 21, the mask chuck 2400 may be horizontally disposed between the deposition source 2200 and the substrate chuck 2300 in the process chamber 2100 and may support the edge portion of the deposition mask 4000. For example, the mask chuck 2400 may have a circular ring shape and may be an electrostatic chuck that holds the bottom edge portion of the deposition mask 4000 using an electrostatic force. However, unlike the above, the mask chuck 2400 may have a quadrilateral plate shape with a circular opening.

The deposition apparatus 2000 may include a lattice support 2410 for supporting the mask cell regions 4210 of the deposition mask 4000. For example, the lattice support 2410 may include a lattice plate 2412 for supporting a rib region 4120 of the mask frame 4100, a support ring 2414 extending downward from the edge portion of the lattice plate 2412, and a flange 2416 surrounding the lower portion of the support ring 2414. The lattice plate 2412 may have a disc shape and may have openings 2418 corresponding to the cell openings 4110 of the mask frame 4100. Further, the lattice plate 2412 and the support ring 2414 may be disposed in the mask chuck 2400, and the mask chuck 2400 may be disposed on the flange 2416.

Referring back to FIG. 14, the deposition mask 4000 may be loaded into the process chamber 2100 by the transfer robot, and may be transferred onto the lift fingers 2500 above the mask chuck 2400. The edge portions of the deposition mask 4000 may be placed on the ends of the lift fingers 2500, and the finger drivers 2510 may lower the lift fingers 2500 to load the deposition mask 4000 onto the mask chuck 2400. In this case, although not illustrated, recesses (not illustrated) into which the lift fingers 2500 are inserted may be provided at the edge portions of the top surface of the mask chuck 2400, and the finger drivers 2510 may rotate the lift fingers 2500 such that the lift fingers 2500 do not overlap the mask chuck 2400 after the deposition mask 4000 is loaded on the mask chuck 2400.

The deposition apparatus 2000 may include a substrate chuck driver 2600 for moving the substrate chuck 2300 and a mask chuck driver 2700 for moving the mask chuck 2400. For example, the substrate chuck driver 2600 may move the substrate chuck 2300 in the first direction DR1, the second direction DR2, and the third direction DR3 in association with adjusting the position of the backplane substrate 3000. In this case, the first direction DR1 may be the first horizontal direction, the second direction DR2 may be the second horizontal direction perpendicular to the first direction DR1, and the third direction DR3 may be the vertical direction. That is, the first direction DR1, the second direction DR2, and the third direction DR3 may be the X-axis direction, the Y-axis direction, and the Z-axis direction, respectively.

The substrate chuck driver 2600 may rotate the substrate chuck 2300 around the Z-axis in order in association with adjusting the azimuth of the backplane substrate 3000. Further, the substrate chuck driver 2600 may rotate the substrate chuck 2300 around the X-axis, and may rotate the substrate chuck 2300 around the Y-axis in order in association with adjusting the inclination of the backplane substrate 3000. For example, the substrate chuck driver 2600 may include a hexapod actuator 2610 that provides a motion of six degrees of freedom (X, Y, Z, θx, θy, and θz).

The substrate chuck driver 2600 may include a substrate stage 2620 to which the hexapod actuator 2610 is mounted, and a second actuator 2630 connected to the substrate stage 2620. The substrate stage 2620 may be disposed horizontally in the process chamber 2100, and the second actuator 2630 may be disposed above the process chamber 2100. The second actuator 2630 may be connected to the substrate stage 2620 by a plurality of driving shafts 2632 extending in the third direction DR3, i.e., the vertical direction (Z-axis direction) through the upper lid of the process chamber 2100, and may move the substrate stage 2620 in the central axis direction of the hexapod actuator 2610, i.e., the vertical direction. For example, the second actuator 2630 may be configured using a brushless DC motor, a linear motor, a direct drive (DD) motor, or the like, and may adjust the height of the substrate chuck 2300 for loading or unloading the backplane substrate 3000.

Although not illustrated in detail, the hexapod actuator 2610 may include a first platform connected to the substrate chuck 2300, a second platform mounted to the substrate stage 2620, and six sub-actuators disposed between the first platform and the second platform. The six sub-actuators may move and rotate the first platform in association with adjusting the horizontal position of the backplane substrate 3000, the vertical position of the backplane substrate 3000, the azimuth of the backplane substrate 3000, and the inclination of the backplane substrate 3000. For example, the six sub-actuators may each be configured using a brushless DC motor, a voice coil linear motor, a step motor, a direct drive (DD) motor, a servo motor, or the like.

The mask chuck driver 2700 may move and rotate the mask chuck 2400 in association with adjusting the horizontal position of the deposition mask 4000 and the azimuth of the deposition mask 4000. The mask chuck driver 2700 may move the mask chuck 2400 in a direction parallel to the deposition mask 4000 and rotate the mask chuck 2400 with respect to the central axis of the mask chuck 2400. For example, the mask chuck driver 2700 may move the mask chuck 2400 in the first direction DR1 (X-axis) and the second direction DR2 (Y-axis), and may rotate the mask chuck 2400 with respect to the third direction DR3 (Z-axis).

The mask chuck driver 2700 may include, e.g., a piezo actuator 2710 that provides a motion of three degrees of freedom (X, Y, and Oz). The piezo actuator 2710 may have a circular ring or quadrilateral ring shape, and the mask chuck 2400 may be disposed on the piezo actuator 2710. The mask chuck driver 2700 may include a mask stage 2720 that is horizontally disposed in the process chamber 2100 and supports the piezo actuator 2710. For example, the mask stage 2720 may have an opening for exposing the deposition mask 4000 toward the deposition source 2200, and may be supported by a plurality of posts 2722 connected to the upper lid of the process chamber 2100. Since, however, the support structure of the mask stage 2720 may be variously changed, the scope of the present disclosure is not be limited thereby.

Referring back to FIG. 21, the deposition apparatus 2000 may include a plurality of gap sensors 2800 for measuring the gap between the substrate chuck 2300 and the mask chuck 2400. For example, the plurality of gap sensors 2800 may be arranged on the edge portions of the substrate chuck 2300, and the gap sensors 2800 may measure the gap to the mask chuck 2400 through the through holes 2310 penetrating the edge portions of the substrate chuck 2300.

After the backplane substrate 3000 and the deposition mask 4000 are loaded onto the substrate chuck 2300 and the mask chuck 2400, respectively, the second actuator 2630 may lower the backplane substrate 3000 to a preset height, and the hexapod actuator 2610 may adjust the height of the substrate chuck 2300 such that the gap between the backplane substrate 3000 and the deposition mask 4000 becomes a preset gap, e.g., about 100 μm to about 200 μm. Next, the gaps between the substrate chuck 2300 and the mask chuck 2400 may be measured by the gap sensors 2800, and the hexapod actuator 2610 may adjust the parallelism between the substrate chuck 2300 and the mask chuck 2400 based on measurements of the gaps as provided by the gap sensors 2800. For example, capacitive proximity sensors may be used as the gap sensors 2800, and the hexapod actuator 2610 may adjust the parallelism between the substrate chuck 2300 and the mask chuck 2400 by adjusting the inclination of the substrate chuck 2300.

Although not illustrated, the deposition apparatus 2000 may further include a plurality of second gap sensors (not illustrated) for measuring the gap between the substrate chuck 2300 and the mask chuck 2400. For example, the plurality of second gap sensors may be arranged on the edge portions of the substrate chuck 2300, and the second gap sensors may measure the gap to the mask chuck 2400 through second through holes (not illustrated) penetrating the edge portions of the substrate chuck 2300. In this case, the hexapod actuator 2610 may adjust the height of the substrate chuck 2300 such that the gap between the backplane substrate 3000 and the deposition mask 4000 becomes a preset gap, e.g., about 10 μm to about 50 μm, and the gap between the substrate chuck 2300 and the mask chuck 2400 may be secondarily measured by the second gap sensors. The hexapod actuator 2610 may secondarily adjust the parallelism between the substrate chuck 2300 and the mask chuck 2400 based on the gaps measured by the second gap sensors. For example, confocal sensors having a resolution higher than a resolution of the capacitive proximity sensors may be used as the second gap sensors.

As described herein, after the parallelism between the substrate chuck 2300 and the mask chuck 2400 is adjusted, the alignment between the backplane substrate 3000 and the deposition mask 4000 may be performed. For example, although not illustrated, a plurality of substrate alignment keys (not illustrated) may be arranged on the edge portions of the backplane substrate 3000, and a plurality of mask alignment keys (not illustrated) corresponding to the plurality of substrate alignment keys may be arranged on the edge portions of the deposition mask 4000. Further, the deposition apparatus 2000 may include a camera unit (not illustrated) for detecting the substrate alignment keys and the mask alignment keys, and an illumination unit (not illustrated) for illuminating the substrate alignment keys and the mask alignment keys, and the substrate chuck 2300 and/or the mask chuck 2400 may be provided with a through hole (not illustrated) for providing illumination light and detecting the substrate alignment keys and the mask alignment keys.

For example, the illumination unit may provide near infrared (NIR) or short wave infrared (SWIR) light, e.g., infrared light having a wavelength of about 1010 nm to about 1020 nm, and the camera unit may detect infrared light transmitted through the backplane substrate 3000 and the deposition mask 4000. The hexapod actuator 2610 may perform alignment between the backplane substrate 3000 and the deposition mask 4000 based on positional information of the substrate alignment keys and the mask alignment keys acquired by the camera unit. For example, the hexapod actuator 2610 may adjust the position and azimuth of the substrate chuck 2300 based on image information acquired by the camera unit.

In some embodiments, in the above, the alignment between the backplane substrate 3000 and the deposition mask 4000 is performed after the parallelism adjustment between the substrate chuck 2300 and the mask chuck 2400 is performed, but in some embodiments, unlike the above, the parallelism adjustment between the substrate chuck 2300 and the mask chuck 2400 may be performed after the alignment between the backplane substrate 3000 and the deposition mask 4000 is performed. Further, in some embodiments, unlike the above, the alignment between the backplane substrate 3000 and the deposition mask 4000 may be performed by the piezo actuator 2710.

As described herein, after the parallelism adjustment between the substrate chuck 2300 and the mask chuck 2400 and the alignment between the backplane substrate 3000 and the deposition mask 4000 are performed, the backplane substrate 3000 may be positioned on the deposition mask 4000. For example, the hexapod actuator 2610 may adjust the height of the substrate chuck 2300 such that the gap between the backplane substrate 3000 and the deposition mask 4000 becomes a preset gap, e.g., a gap of several μm. In another example, the hexapod actuator 2610 may adjust the height of the substrate chuck 2300 such that the backplane substrate 3000 is brought into contact with the deposition mask 4000.

After the backplane substrate 3000 is positioned on the deposition mask 4000, the gaps between the backplane substrate 3000 and the deposition mask 4000 may be measured by the sensors 3100 on the backplane substrate 3000. In this case, as illustrated in FIGS. 20 and 21, a signal detector 2900 for detecting measurement signals may be disposed in the mask chuck 2400.

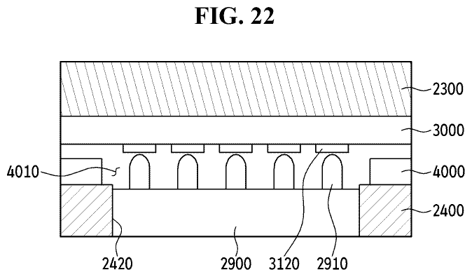

FIG. 22 is a schematic cross-sectional view illustrating the signal detector illustrated in FIG. 21.

Referring to FIG. 22, a slot 2420 into which the signal detector 2900 is inserted may be provided at the edge portion of the mask chuck 2400, and the deposition mask 4000 may have a through opening 4010 exposing the signal detector 2900. In this case, the contact pads 3120 on the backplane substrate 3000 may be arranged facing the signal detector 2900 through the through opening 4010 of the deposition mask 4000. The signal detector 2900 may include a plurality of probe pins 2910 for detecting measurement signals, and the probe pins 2910 may be respectively brought into contact with the contact pads 3120 on the backplane substrate 3000 through the through opening 4010 of the deposition mask 4000.

The signal detector 2900 may detect the capacitance between the measurement electrodes 3110 on the backplane substrate 3000 and the membrane 4200 of the deposition mask 4000 or the capacitance between the measurement electrodes 3110 on the backplane substrate 3000 and the spacers 4400 on the membrane 4200, thereby measuring the gaps between the backplane substrate 3000 and the deposition mask 4000. The substrate chuck driver 2600 may adjust the parallelism between the backplane substrate 3000 and the deposition mask 4000 based on the gaps between the backplane substrate 3000 and the deposition mask 4000 measured by the sensors 3100 (i.e., based on measurements of the gaps between the backplane substrate 3000 and the deposition mask 4000 as provided by the sensors). Specifically, the hexapod actuator 2610 may adjust the inclination of the substrate chuck 2300 such that all the gaps between the backplane substrate 3000 and the deposition mask 4000 satisfy a preset tolerance range, thus supporting making the gap between the backplane substrate 3000 and the deposition mask 4000 uniform and improving the parallelism between the backplane substrate 3000 and the deposition mask 4000.

In another example, when the sensors 3200 illustrated in FIG. 19 are arranged on the backplane substrate 3000, the signal detector 2900 may have probe pins respectively corresponding to the first and second contact pads 3230 and 3240, and may determine whether or not the first and second contact electrodes 3210 and 3220 on the backplane substrate 3000 are in contact with the spacers 4400 on the deposition mask 4000. In this case, the hexapod actuator 2610 may adjust the inclination of the substrate chuck 2300 such that both the first and second contact electrodes 3210 and 3220 on the backplane substrate 3000 are brought into contact with the spacers 4400 on the deposition mask 4000, which thus supports making the gap between the backplane substrate 3000 and the deposition mask 4000 uniform and improving the parallelism between the backplane substrate 3000 and the deposition mask 4000.

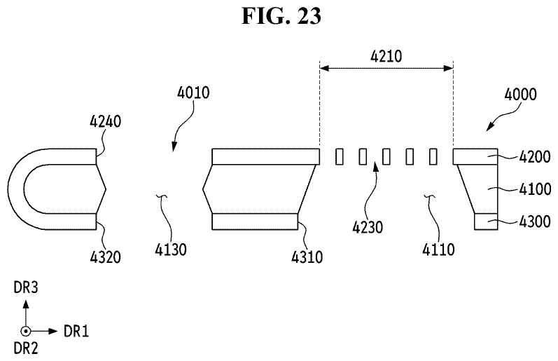

FIG. 23 is a schematic enlarged cross-sectional view illustrating the through opening of the deposition mask illustrated in FIG. 22.

Referring to FIG. 23, the deposition mask 4000 may have the through opening 4010 formed through the mask frame 4100, the membrane 4200, and the rear inorganic film 4300. The through opening 4010 may expose the contact pads 3120 on the backplane substrate 3000 when the backplane substrate 3000 is positioned on the deposition mask 4000. For example, the through opening 4010 may include a first opening 4240 penetrating the membrane 4200, a second opening 4320 penetrating the rear inorganic film 4300, and a third opening 4130 penetrating the mask frame 4100.

The first opening 4240 may be formed simultaneously with the pixel openings 4230. For example, the pixel openings 4230 and the first opening 4240 may be formed by forming a photoresist pattern (not illustrated) that exposes portions where the pixel openings 4230 and the first opening 4240 are to be formed on the membrane 4200, and then performing an anisotropic etching process using the photoresist pattern as an etching mask until the mask frame 4100 is exposed.

The second opening 4320 may be formed simultaneously with the rear openings 4310. For example, the rear openings 4310 and the second openings 4320 may be formed by forming a photoresist pattern (not illustrated) that exposes portions where the rear openings 4310 and the second openings 4320 are to be formed on the rear inorganic film 4300, and then performing an anisotropic etching process using the photoresist pattern as an etching mask until the rear surface of the mask frame 4100 is exposed.

The third opening 4130 may be formed simultaneously with the cell openings 4110. For example, the cell openings 4110 and the third opening 4130 may be formed through a wet etching process using tetramethylammonium hydroxide (TMAH) or potassium hydroxide (KOH). In this case, the membrane 4200 and the rear inorganic film 4300 may function as an etching mask for forming the third opening 4130.

In another example, although not illustrated, the through opening 4010 may be pre-provided at a single crystal silicon substrate used as the mask frame 4100. Specifically, the through opening 4010 may be pre-formed by a laser cutting process when the single crystal silicon substrate is in a bare wafer state.

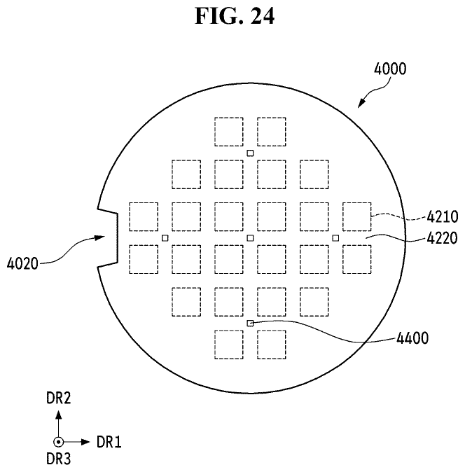

FIG. 24 is a plan view illustrating a deposition mask according to another embodiment of the present disclosure.

Referring to FIG. 24, the deposition mask 4000 may have a recess 4020 for exposing the contact pads 3120 of the backplane substrate 3000 when the backplane substrate 3000 is positioned on the deposition mask 4000. For example, the recess 4020 may be formed at the side surface of the deposition mask 4000, and may be formed in the same manner as the through opening 4010 described with reference to FIG. 23. In another example, the recess 4020 may be pre-provided at a single crystal silicon substrate used as the mask frame 4100. Specifically, the recess 4020 may be pre-formed by a laser cutting process when the single crystal silicon substrate is in a bare wafer state.

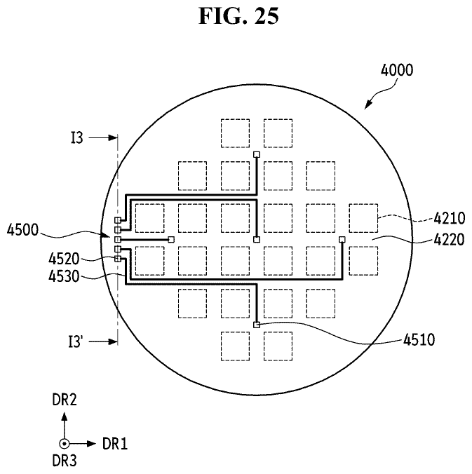

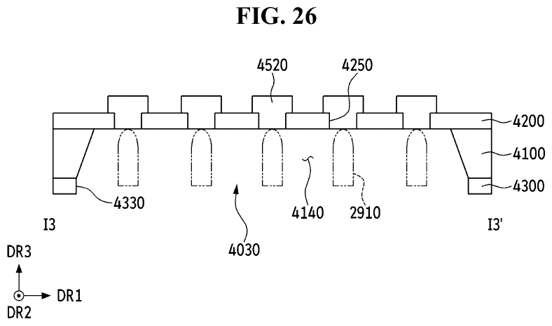

FIG. 25 is a schematic plan view illustrating a deposition mask according to still another embodiment of the present disclosure. FIG. 26 is a schematic enlarged cross-sectional view taken along line I3-I3′ illustrated in FIG. 25.

Referring to FIGS. 25 and 26, a plurality of sensors 4500 for measuring gaps between the backplane substrate 3000 and the deposition mask 4000 may be formed on the deposition mask 4000. For example, each of the plurality of sensors 4500 may include a measurement electrode 4510, a contact pad 4520, and a wiring 4530, and may be disposed on the membrane 4200. Specifically, the plurality of measurement electrodes 4510 may be arranged on the grid region 4220 of the membrane 4200 at preset measuring points, and the plurality of contact pads 4520 may be arranged on the edge portion of the membrane 4200. The plurality of wirings 4530 may connect the measurement electrodes 4510 and the contact pads 4520 and may be arranged on the grid region 4220 of the membrane 4200. As illustrated, five sensors 4500 are arranged on the deposition mask 4000, but the positions and number of the sensors 4500 may be variously changed and the scope of the present disclosure is not limited thereby.

The measurement electrodes 4510, the contact pads 4520, and the wirings 4530 may be formed of a conductive material, e.g., metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

For example, after a conductive material layer is formed on the membrane 4200, the conductive material layer may be patterned to simultaneously form the measurement electrodes 4510, the contact pads 4520, and the wirings 4530 on the membrane 4200. Specifically, although not illustrated, after a photoresist pattern (not illustrated) the exposes portions other than portions where the measurement electrodes 4510, the contact pads 4520, and the wirings 4530 are to be formed is formed on the conductive material layer, an anisotropic etching process using the photoresist pattern as an etching mask may be performed to form the measurement electrodes 4510, the contact pads 4520, and the wirings 4530 on the membrane 4200. In another example, the measurement electrodes 4510, the contact pads 4520, and the wirings 4530 may be formed by a damascene process.

In particular, pad openings 4250 penetrating the membrane 4200 may be formed before the conductive material layer is formed. For example, the pad openings 4250 may be formed simultaneously with the pixel openings 4230. For example, the pixel openings 4230 and the pad openings 4250 may be formed by forming a photoresist pattern (not illustrated) that exposes portions where the pixel openings 4230 and the pad openings 4250 are to be formed on the membrane 4200, and then performing an anisotropic etching process using the photoresist pattern as an etching mask until the mask frame 4100 is exposed. In this case, the conductive material layer may be formed on the membrane 4200 such that the pad openings 4250 are buried, and may be patterned such that the contact pads 4520 are positioned in the pad openings 4250.

According to the present embodiment, the deposition mask 4000 may have a sensor opening 4030 exposing the contact pads 4520. The sensor opening 4030 may include a fourth opening 4330 penetrating the rear inorganic film 4300, and a fifth opening 4140 penetrating the mask frame 4100.

The fourth opening 4330 may be formed simultaneously with the rear openings 4310. For example, the rear openings 4310 and the fourth openings 4330 may be formed by forming a photoresist pattern (not illustrated) that exposes portions where the rear openings 4310 and the fourth openings 4330 are to be formed on the rear inorganic film 4300, and then performing an anisotropic etching process using the photoresist pattern as an etching mask until the rear surface of the mask frame 4100 is exposed.

The fifth opening 4140 may be formed simultaneously with the cell openings 4110. For example, the cell openings 4110 and the fifth opening 4140 may be formed through a wet etching process using tetramethylammonium hydroxide (TMAH) or potassium hydroxide (KOH). In this case, the rear inorganic film 4300 may function as an etching mask for forming the cell openings 4110 and the fifth opening 4140.

According to the present embodiment, when the deposition mask 4000 is loaded onto the mask chuck 2400, the probe pins 2910 of the signal detector 2900 may be brought into contact with the contact pads 4520 through the sensor opening 4030. Further, when the backplane substrate 3000 is positioned on the deposition mask 4000, the signal detector 2900 may detect the capacitance between the pixel defining film PDL on the backplane substrate 3000 and the measurement electrodes 4510 on the deposition mask 4000 by using the probe pins 2910, thereby measuring the gaps between the backplane substrate 3000 and the deposition mask 4000.

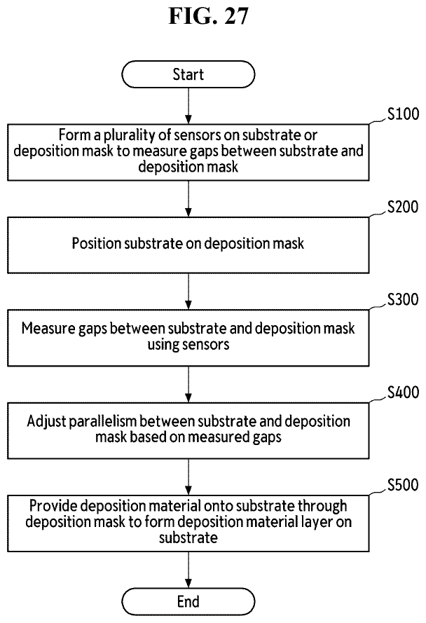

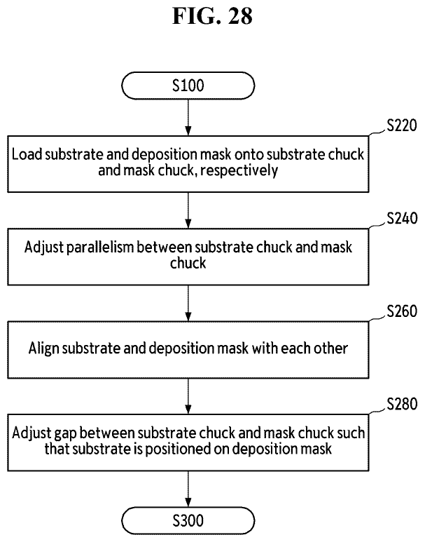

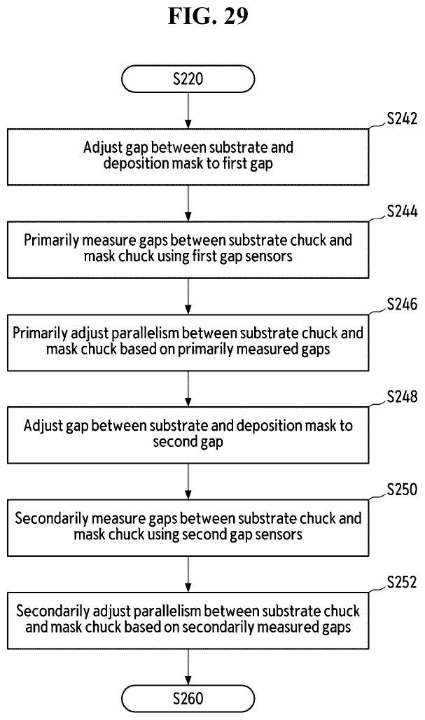

FIG. 27 is a flowchart illustrating a deposition method according to still another embodiment of the present disclosure. FIG. 28 is a flowchart illustrating step S200 illustrated in FIG. 27. FIG. 29 is a flowchart illustrating step S240 illustrated in FIG. 28.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIGS. 27 to 29, in step S100, the method may include forming a plurality of sensors on the backplane substrate 3000 or the deposition mask 4000, and measuring the gaps between the backplane substrate 3000 and the deposition mask 4000 using the plurality of sensors. For example, as illustrated in FIG. 15, the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 intersecting the first direction DR1, and the display cell regions 3010 may be respectively individualized into a plurality of display panels 100 by a dicing process after the display manufacturing process is completed. Although not illustrated in detail, each of the display cell regions 3010 may include the semiconductor backplane SBP and the light emitting element backplane EBP disposed on the semiconductor backplane SBP, and the plurality of electrode patterns AND may be disposed on the light emitting element backplane EBP. Further, the pixel defining film PDL may be disposed on the display cell regions 3010 and the scribe lane region 3020, and the pixel defining film PDL may have a plurality of openings exposing the electrode patterns AND.

The plurality of sensors 3100 may be formed on the backplane substrate 3000 and may measure the gaps between the backplane substrate 3000 and the deposition mask 4000. For example, as illustrated in FIG. 15, each of the plurality of sensors 3100 may include the measurement electrode 3110, the contact pad 3120, and the wiring 3130, and may be arranged on the pixel defining film PDL. Specifically, the plurality of measurement electrodes 3110 may be respectively disposed on the scribe lane region 3020 at preset measuring points, and the plurality of contact pads 3120 may be arranged on the edge portion of the backplane substrate 3000. The plurality of wirings 3130 may connect the measurement electrodes 3110 and the contact pads 3120 and may be disposed on the scribe lane region 3020. As illustrated in FIG. 15, five sensors 3100 are arranged on the backplane substrate 3000, but the positions and number of the sensors 3100 may be variously changed and the scope of the present disclosure is not limited thereby.

The measurement electrodes 3110, the contact pads 3120, and the wirings 3130 may be formed of a conductive material, e.g., metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

For example, after a conductive material layer is formed on the pixel defining film PDL, the conductive material layer may be patterned to simultaneously form the measurement electrodes 3110, the contact pads 3120, and the wirings 3130 on the pixel defining film PDL. Specifically, although not illustrated, after a photoresist pattern (not illustrated) that exposes portions other than portions where the measurement electrodes 3110, the contact pads 3120, and the wirings 3130 are to be formed is formed on the conductive material layer, an anisotropic etching process using the photoresist pattern as an etching mask may performed to form the measurement electrodes 3110, the contact pads 3120, and the wirings 3130 on the pixel defining film PDL. In another example, the measurement electrodes 3110, the contact pads 3120, and the wirings 3130 may be formed by a damascene process.

As illustrated in FIGS. 16 to 18, the deposition mask 4000 may include the mask cell regions 4210 respectively corresponding to the display cell regions 3010 of the backplane substrate 3000. Each of the mask cell regions 4210 may have the plurality of pixel openings 4230 exposing the electrode patterns AND of the backplane substrate 3000 in a deposition process.

For example, the deposition mask 4000 may include the mask frame 4100 and the membrane 4200 disposed on the mask frame 4100. In this case, the membrane 4200 may include the plurality of mask cell regions 4210 and the grid region 4220 disposed between the mask cell regions 4210, and each of the mask cell regions 4210 may have the plurality of pixel openings 4230. The mask frame 4100 may have cell openings 4110, and may include the rib region 4120 defining the cell openings 4110. In this case, the mask cell regions 4210 may be respectively arranged on the cell openings 4110, and the grid region 4220 may be disposed on the rib region 4120. Further, the mask cell regions 4210 may be exposed through the cell openings 4110, and the pixel openings 4230 may be connected to the cell openings 4110 while penetrating the mask cell regions 4210.

The mask cell regions 4210 may be arranged in a matrix form along the first direction DR1 and the second direction DR2, as illustrated in FIG. 16. For example, the mask cell regions 4210 may be arranged in a matrix form along the first horizontal direction DR1 and the second horizontal direction DR2 perpendicular to the first horizontal direction DR1, and may be arranged to respectively correspond to the display cell regions 3010 of the backplane substrate 3000.

The membrane 4200 may be disposed on the front surface of the mask frame 4100, and the rear inorganic film 4300 may be disposed on the rear surface of the mask frame 4100. The membrane 4200 and the rear inorganic film 4300 may be formed of the same material. For example, the membrane 4200 and the rear inorganic film 4300 may be formed of an inorganic material such as, for example, silicon nitride (SiNx), and may be formed to have a thickness of about 0.5 μm to about 3 μm by a thermal chemical vapor deposition (TCVD) process. That is, the front inorganic film and the rear inorganic film 4300 may be simultaneously formed on the front surface and the rear surface of the mask frame 4100 by the TCVD process, respectively, and the front inorganic film may be used as the membrane 4200.

A single crystal silicon substrate may be used as the mask frame 4100, and the pixel openings 4230 may be formed by forming the membrane 4200 on the mask frame 4100 and then patterning the membrane 4200. For example, the pixel openings 4230 may be formed by forming a photoresist pattern (not illustrated) that exposes portions where the pixel openings 4230 are to be formed on the membrane 4200, and then performing an anisotropic etching process using the photoresist pattern as an etching mask until the mask frame 4100 is exposed.

The rear inorganic film 4300 may have rear openings 4310 communicating with the cell openings 4110, and may function as an etching mask in an etching process for forming the cell openings 4110. For example, the rear openings 4310 may be formed by forming a photoresist pattern (not illustrated) that exposes portions where the rear openings 4310 are to be formed on the rear inorganic film 4300, and then performing an anisotropic etching process using the photoresist pattern as an etching mask until the rear surface of the mask frame 4100 is exposed.

The cell openings 4110 may be formed to expose the mask cell regions 4210 of the membrane 4200 through an anisotropic etching process using the rear inorganic film 4300 as an etching mask. For example, the cell openings 4110 may be formed through a wet etching process using tetramethylammonium hydroxide (TMAH) or potassium hydroxide (KOH). In this case, the <100> crystal direction of the single crystal silicon substrate used as the mask frame 4100 may be the third direction DR3, such that the cell openings 4110 may be formed to have a width that gradually decreases toward the membrane 4200, i.e., in the third direction DR3, by the wet etching process. For example, each of the inner surfaces of the cell openings 4110 may be formed to have an inclination of about 54.74°.

As described herein, when the sensors 3100 are arranged on the backplane substrate 3000, the gaps between the backplane substrate 3000 and the deposition mask 4000 may be measured based on the capacitance between the measurement electrodes 3110 and the membrane 4200.

In another example, the spacers 4400 respectively corresponding to the sensors 3100 on the backplane substrate 3000 may be formed on the deposition mask 4000. In particular, the spacers 4400 may be formed on the grid region 4220 of the deposition mask 4000 to respectively correspond to the measurement electrodes 3110. In an example in which the backplane substrate 3000 is positioned on the deposition mask 4000, the measurement electrodes 3110 and the spacers 4400 face each other, and the gaps between the measurement electrodes 3110 and the spacers 4400 may be measured according to the capacitance between the measurement electrodes 3110 and the spacers 4400. In this case, each of the spacers 4400 may be used as a sensor dog (or detection target) for measuring the gap between the backplane substrate 3000 and the deposition mask 4000, and the gaps between the backplane substrate 3000 and the deposition mask 4000 may be calculated from the gaps between the measurement electrodes 3110 and the spacers 4400.

The spacers 4400 may be formed of a dielectric material or a conductive material. For example, the spacers 4400 may be formed of a dielectric material such as, for example, silicon oxide (SiOx), silicon nitride (SiNx), silicon oxynitride (SiON), aluminum oxide (AlOx), hafnium oxide (HfOx), zirconium oxide (ZrOx), or the like. In another example, the spacers 4400 may be formed of metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

The spacers 4400 may be formed on the membrane 4200 after the membrane 4200 is formed. In this case, the pixel openings 4230 may be formed after the spacers 4400 are formed. In particular, the spacers 4400 may be formed on the grid region 4220 of the membrane 4200 to correspond to the measurement electrodes 3110 on the backplane substrate 3000. For example, after a dielectric material layer or a conductive material layer is formed on the membrane 4200, the spacers 4400 may be formed on the membrane 4200 by patterning the dielectric material layer or the conductive material layer. Specifically, although not illustrated, after a photoresist pattern (not illustrated) that exposes portions other than portions where the spacers 4400 are to be formed is formed on the dielectric material layer or the conductive material layer, an anisotropic etching process using the photoresist pattern as an etching mask may be performed until the membrane 4200 is exposed to form the spacers 4400 on the membrane 4200.

In another example, as illustrated in FIG. 19, the plurality of sensors 3200, each including the first contact electrode 3210, the second contact electrode 3220, the first contact pad 3230, the second contact pad 3240, the first wiring 3250, and the second wiring 3260 may be formed on the backplane substrate 3000. The first and second contact electrodes 3210 and 3220 may be formed on a plurality of preset measuring points in the scribe lane region 3020, and the first and second contact pads 3230 and 3240 may be formed on the edge portion of the backplane substrate 3000. The first and second wirings 3250 and 3260 may connect the first and second contact electrodes 3210 and 3220 and the first and second contact pads 3230 and 3240, and may be formed on the scribe lane region 3020.

The first and second contact electrodes 3210 and 3220, the first and second contact pads 3230 and 3240, and the first and second wirings 3250 and 3260 may be formed of a conductive material, e.g., metal such as, for example, copper (Cu), aluminum (Al), tungsten (W), molybdenum (Mo), chromium (Cr), gold (Au), titanium (Ti), nickel (Ni), neodymium (Nd), oxide or nitride of the metal, or transparent conductive oxide such as, for example, indium tin oxide (ITO), zinc oxide (ZnO), indium zinc oxide (IZO), or the like.

For example, after a conductive material layer is formed on the pixel defining film PDL, the conductive material layer may be pattered to form the first and second contact electrodes 3210 and 3220, the first and second contact pads 3230 and 3240, and the first and second wirings 3250 and 3260 on the pixel defining film PDL. Specifically, although not illustrated, a photoresist pattern (not illustrated) that exposes portions where the first and second contact electrodes 3210 and 3220, the first and second contact pads 3230 and 3240, and the first and second wirings 3250 and 3260 are to be formed is formed on the conductive material layer, an anisotropic etching process using the photoresist pattern as an etching mask may be performed to form the first and second contact electrodes 3210 and 3220, the first and second contact pads 3230 and 3240, and the first and second wirings 3250 and 3260 on the pixel defining film PDL. In another example, the first and second contact electrodes 3210 and 3220, the first and second contact pads 3230 and 3240, and the first and second wirings 3250 and 3260 may be formed by a damascene process.

When each of the sensors 3200 includes the first and second contact electrodes 3210 and 3220 as described herein, the spacers 4400 of the deposition mask 4000 may be formed of a conductive material. In particular, when the backplane substrate 3000 is positioned on the deposition mask 4000, the first and second contact electrodes 3210 and 3220 may be in contact with the spacer 4400 corresponding thereto, and the first contact electrode 3210 and the second contact electrode 3220 may be electrically connected through the corresponding spacer 4400. In particular, when the first contact electrode 3210 and the second contact electrode 3220 are electrically connected, it may be determined that the first and second contact electrodes 3210 and 3220 and the spacer 4400 are in contact with each other at the corresponding point(s) of contact between the first and second contact electrodes 3210 and 3220 and the spacer 4400, and when the first contact electrode 3210 and the second contact electrode 3220 are not electrically connected, it may be determined that the first and second contact electrodes 3210 and 3220 and the spacer 4400 are not in contact with each other at the corresponding point(s) of contact between the first and second contact electrodes 3210 and 3220 and the spacer 4400. As a result, the gaps between the backplane substrate 3000 and the deposition mask 4000 may be measured depending on whether the first contact electrode 3210 and the second contact electrode 3220 are electrically connected at the plurality of measuring points.

Referring to FIGS. 27 and 28, in step S200, the method may include positioning the backplane substrate 3000 on the deposition mask 4000. Specifically, in step S220, the method may include loading the backplane substrate 3000 and the deposition mask 4000 onto the substrate chuck 2300 and the mask chuck 2400, respectively.

For example, the backplane substrate 3000 may be loaded into the process chamber 2100 by a transfer robot (not illustrated), and may be transferred from the transfer robot onto the lift fingers 2500 under the substrate chuck 2300. In this case, the rear surface of the backplane substrate 3000 may face the bottom surface of the substrate chuck 2300, and the lift fingers 2500 may support the front edge portions of the backplane substrate 3000. The finger drivers 2510 may raise the lift fingers 2500 such that the backplane substrate 3000 becomes adjacent to the bottom surface of the substrate chuck 2300 and, then, the rear surface of the backplane substrate 3000 may be held on the bottom surface of the substrate chuck 2300 by an electrostatic force.

The deposition mask 4000 may be loaded into the process chamber 2100 by the transfer robot, and may be transferred onto the lift fingers 2500 above the mask chuck 2400. The edge portions of the deposition mask 4000 may be placed on the ends of the lift fingers 2500, and the finger drivers 2510 may lower the lift fingers 2500 to load the deposition mask 4000 onto the mask chuck 2400. In this case, the edge portion of the deposition mask 4000 may be placed on the mask chuck 2400, and the mask cell regions 4210 of the deposition mask 4000 may be placed on the lattice support 2410. Further, the edge portion of the deposition mask 4000 may be held on the mask chuck 2400 by an electrostatic force, and the rib region 4120 of the mask frame 4100 may be supported by the lattice plate 2412.

Referring to FIG. 28 and FIG. 29, in step S240, the method may include adjusting the parallelism between the substrate chuck 2300 and the mask chuck 2400. Specifically, the method may include measuring the gaps between the substrate chuck 2300 and the mask chuck 2400 using the gap sensors, and adjusting the parallelism between the substrate chuck 2300 and the mask chuck 2400 based on measurements of the gaps as provided by the gap sensors.

For example, in step S242, the method may include adjusting the gap between the backplane substrate 3000 and the deposition mask 4000 to a first gap. Specifically, the second actuator 2630 may lower the substrate chuck 2300 to a preset height, and the hexapod actuator 2610 may adjust the height of the substrate chuck 2300 such that the gap between the backplane substrate 3000 and the deposition mask 4000 becomes the first gap, e.g., about 100 μm to about 200 μm.

In step S244, the method may include primarily measuring the gaps between the substrate chuck 2300 and the mask chuck 2400 using the first gap sensors. The first gap sensors may be arranged on the edge portions of the substrate chuck 2300, as illustrated in FIG. 21, and may measure the distance to the mask chuck 2400 through the through holes formed through the edge portions of the substrate chuck 2300. For example, capacitive proximity sensors may be used as the first gap sensors.

In step S246, the method may include primarily adjusting the parallelism between the substrate chuck 2300 and the mask chuck 2400 based on the primarily measuring of the gaps (i.e., based on the primarily measured gaps). For example, the hexapod actuator 2610 may adjust the inclination of the substrate chuck 2300 based on the primarily measured gap, thereby primarily adjusting the parallelism between the substrate chuck 2300 and the mask chuck 2400.

In step S248, the method may include adjusting the gap between the backplane substrate 3000 and the deposition mask 4000 to a second gap smaller than the first gap. Specifically, the hexapod actuator 2610 may adjust the height of the substrate chuck 2300 such that the gap between the backplane substrate 3000 and the deposition mask 4000 becomes a second gap, e.g., about 10 μm to about 50 μm.

In step S250, the method may include secondarily measuring the gaps between the substrate chuck 2300 and the mask chuck 2400 using the second gap sensors. The second gap sensors may be arranged on the edge portions of the substrate chuck 2300, as illustrated in FIG. 21, and may measure the distance to the mask chuck 2400 through the through holes formed through the edge portions of the substrate chuck 2300. For example, confocal sensors having a resolution higher than a resolution of the first gap sensors may be used as the second gap sensors, and may be arranged on the edge portions of the substrate chuck 2300 to be adjacent to the first gap sensors.

In step S252, the method may include secondarily adjusting the parallelism between the substrate chuck 2300 and the mask chuck 2400 based on the secondarily measuring of the gaps (i.e., based on the secondarily measured gaps). For example, the hexapod actuator 2610 may adjust the inclination of the substrate chuck 2300 based on the secondarily measured gaps, thereby secondarily adjusting the parallelism between the substrate chuck 2300 and the mask chuck 2400.

Referring to FIG. 28, after the parallelism between the substrate chuck 2300 and the mask chuck 2400 is adjusted as described herein, the method may include aligning the backplane substrate 3000 and the deposition mask 4000 with each other in step S260. For example, although not illustrated, a plurality of substrate alignment keys (not illustrated) may be arranged on the edge portions of the backplane substrate 3000, and a plurality of mask alignment keys (not illustrated) corresponding to the plurality of substrate alignment keys may be arranged on the edge portions of the deposition mask 4000. Further, the deposition apparatus 2000 may include a camera unit (not illustrated) for detecting the substrate alignment keys and the mask alignment keys, and an illumination unit (not illustrated) for illuminating the substrate alignment keys and the mask alignment keys, and the substrate chuck 2300 and/or the mask chuck 2400 may be provided with a through hole (not illustrated) for providing illumination light and detecting the substrate alignment keys and the mask alignment keys.

For example, the illumination unit may provide near infrared (NIR) or short wave infrared (SWIR) light, e.g., infrared light having a wavelength of about 1010 nm to about 1020 nm, and the camera unit may detect infrared light transmitted through the backplane substrate 3000 and the deposition mask 4000. The hexapod actuator 2610 may perform alignment between the backplane substrate 3000 and the deposition mask 4000 based on positional information of the substrate alignment keys and the mask alignment keys acquired by the camera unit. For example, the hexapod actuator 2610 may adjust the X-axis direction position, the Y-axis direction position, and the azimuth of the substrate chuck 2300 based on the image information acquired by the camera unit.

In some embodiments, in the above, the backplane substrate 3000 and the deposition mask 4000 are aligned with each other after the parallelism between the substrate chuck 2300 and the mask chuck 2400 is secondarily adjusted, but embodiments of the present disclosure are not limited thereto. For example, unlike the above, the backplane substrate 3000 and the deposition mask 4000 may be aligned with each other after the parallelism between the substrate chuck 2300 and the mask chuck 2400 is primarily adjusted.

After the backplane substrate 3000 and the deposition mask 4000 are aligned with each other as described herein, in step S280, the method may include adjusting the gap between the substrate chuck 2300 and the mask chuck 2400 such that the backplane substrate 3000 is positioned on the deposition mask 4000. For example, the hexapod actuator 2610 may adjust the height of the substrate chuck 2300 such that the gap between the backplane substrate 3000 and the deposition mask 4000 becomes a preset gap, e.g., a gap of several μm. In another example, the hexapod actuator 2610 may adjust the height of the substrate chuck 2300 such that the backplane substrate 3000 is brought into contact with the deposition mask 4000.

Referring back to FIG. 27, after the backplane substrate 3000 is positioned on the deposition mask 4000, in step S300, the method may include measuring the gaps between the backplane substrate 3000 and the deposition mask 4000 using sensors. For example, if the sensors 3100, each including the measurement electrode 3110, the contact pad 3120, and the wiring 3130, are formed on the backplane substrate 3000, as illustrated in FIG. 15, the capacitance between the measurement electrodes 3110 and the membrane 4200 of the deposition mask 4000 may be detected by the signal detector 2900, thereby measuring the gaps between the backplane substrate 3000 and the deposition mask 4000.

In another example, as illustrated in FIGS. 16 to 18, when spacers 4400 are formed on the membrane 4200 of the deposition mask 4000, the capacitance between the measurement electrodes 3110 and the spacers 4400 may be detected by the signal detector, thereby measuring the gaps between the backplane substrate 3000 and the deposition mask 4000.

In another example, as illustrated in FIG. 19, when the sensors 3200, each including the first contact electrode 3210, the second contact electrode 3220, the first contact pad 3230, the second contact pad 3240, the first wiring 3250, and the second wiring 3260, are formed on the backplane substrate 3000, the method may include detecting whether or not the first and second contact electrodes 3210 and 3220 and the spacers 4400 are in contact with each other, i.e., whether or not the first and second contact electrodes 3210 and 3220 are electrically connected, by the signal detector 2900, thereby measuring the gaps between the backplane substrate 3000 and the deposition mask 4000.

In another example, as illustrated in FIG. 25, when the sensors 4500, each including the measurement electrode 4510, the contact pad 4520, and the wiring 4530, are formed on the deposition mask 4000, the method may include detecting the capacitance between the pixel defining film PDL on the backplane substrate 3000 and the measurement electrodes 4510 by the signal detector 2900, thereby measuring the gaps between the backplane substrate 3000 and the deposition mask 4000.

After the gaps between the backplane substrate 3000 and the deposition mask 4000 are measured as described herein, in step S400, the method may include adjusting the parallelism between the backplane substrate 3000 and the deposition mask 4000 based on the gaps (i.e., the measurements of the gaps) between the backplane substrate 3000 and the deposition mask 4000. For example, the hexapod actuator 2610 may adjust the inclination of the substrate chuck 2300 such that all the gaps between the backplane substrate 3000 and the deposition mask 4000 satisfy a preset tolerance range. Specifically, the inclination of the substrate chuck 2300 may be adjusted such that all the capacitance values between the measurement electrodes 3110 and the membrane 4200, the capacitance values between the measurement electrodes 3110 and the spacers 4400, or the capacitance values between the measurement electrodes 4510 and the pixel defining film PDL satisfy the tolerance range. In another example, the inclination of the substrate chuck 2300 may be adjusted such that both the first and second contact electrodes 3210 and 3220 are electrically connected. As a result, by executing step S400, the gap between the backplane substrate 3000 and the deposition mask 4000 may become uniform, and the parallelism between the backplane substrate 3000 and the deposition mask 4000 may be improved.

After step S400 is executed, in step S500, the method may include providing a deposition material onto the backplane substrate 3000 through the deposition mask 4000. Providing the deposition material forms a deposition material layer on the backplane substrate 3000. For example, the deposition source 2200 may disperse an organic material (e.g., in a gas or vapor form) for forming light emitting material layers on the backplane substrate 3000, and the dispersed organic material may be deposited on the electrode patterns AND of the backplane substrate 3000 through the pixel openings 4230 of the deposition mask 4000.

The deposition techniques and apparatus according to the embodiments of the present disclosure described herein may improve the parallelism between the backplane substrate 3000 and the deposition mask 4000, such that the pixel position accuracy of the light emitting material layers formed on the backplane substrate 3000 may be improved. Further, the deposition techniques and apparatus described herein may support reducing the color mixing phenomenon between the light emitting material layers.

Aspects of the invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A deposition method comprising:
forming a plurality of sensors on a substrate or a deposition mask which measure gaps between the substrate and the deposition mask;
positioning the substrate on the deposition mask;
measuring the gaps between the substrate and the deposition mask using the plurality of sensors;
adjusting a parallelism between the substrate and the deposition mask based on the measuring of the gaps between the substrate and the deposition mask; and
providing a deposition material onto the substrate through the deposition mask, wherein providing the deposition material forms a deposition material layer on the substrate.

2. The deposition method of claim 1, wherein:
the substrate comprises display cell regions, a scribe lane region disposed between the display cell regions, and an edge region, and
each of the plurality of sensors comprises:
a measurement electrode formed on the scribe lane region;
a contact pad formed on the edge region; and
a wiring formed on the scribe lane region and connecting the measurement electrode and the contact pad.

3. The deposition method of claim 2, wherein each of the gaps between the substrate and the deposition mask is measured based on a capacitance between the measurement electrode and the deposition mask.

4. The deposition method of claim 2, further comprising forming a plurality of spacers on the deposition mask,
wherein each of the gaps between the substrate and the deposition mask is measured based on a capacitance between the measurement electrode and a respective spacer comprised among the plurality of spacers.

5. The deposition method of claim 1, wherein:
the deposition mask comprises mask cell regions, a grid region disposed between the mask cell regions, and an edge region, and
each of the plurality of sensors comprises:
a measurement electrode formed on the grid region;
a contact pad formed on the edge region; and
a wiring formed on the grid region and connecting the measurement electrode and the contact pad.

6. The deposition method of claim 5, wherein each of the gaps between the substrate and the deposition mask is measured based on a capacitance between the measurement electrode and the substrate.

7. The deposition method of claim 1, wherein the positioning of the substrate on the deposition mask comprises:
loading the substrate and the deposition mask onto a substrate chuck and a mask chuck, respectively, such that the substrate and the deposition mask face each other;
adjusting a parallelism between the substrate chuck and the mask chuck;
aligning the substrate and the deposition mask with each other; and
adjusting a gap between the substrate chuck and the mask chuck such that the substrate is positioned on the deposition mask.

8. The deposition method of claim 7, wherein the adjusting of the parallelism between the substrate chuck and the mask chuck comprises:
measuring gaps between the substrate chuck and the mask chuck using gap sensors arranged on the substrate chuck; and
adjusting an inclination of the substrate chuck based on the measuring of the gaps between the substrate chuck and the mask chuck.

9. A deposition apparatus comprising:
a deposition source providing a deposition material onto a substrate;
a mask chuck disposed above the deposition source and supporting a deposition mask;
a substrate chuck disposed above the mask chuck and supporting the substrate such that the substrate faces the deposition mask; and
a substrate chuck driver adjusting a position and an inclination of the substrate chuck in association with positioning the substrate on the deposition mask and adjusting a parallelism between the substrate and the deposition mask,
wherein a plurality of sensors for measuring gaps between the substrate and the deposition mask are disposed on the substrate or the deposition mask, and
the substrate chuck driver adjusts the inclination of the substrate chuck based on measurements of the gaps between the substrate and the deposition mask as provided by the plurality of sensors.

10. The deposition apparatus of claim 9, wherein:
the substrate comprises display cell regions, a scribe lane region disposed between the display cell regions, and an edge region, and
each of the plurality of sensors comprises:
a measurement electrode formed on the scribe lane region;
a contact pad formed on the edge region; and
a wiring disposed on the scribe lane region and connecting the measurement electrode and the contact pad.

11. The deposition apparatus of claim 10, further comprising a signal detector comprising a plurality of probe pins in contact with contact pads of the plurality of sensors.

12. The deposition apparatus of claim 11, wherein:
the signal detector is disposed in the mask chuck, and
the deposition mask has a through hole or a recess through which the plurality of probe pins pass.

13. The deposition apparatus of claim 11, wherein the signal detector respectively detects capacitances between the measurement electrodes of the sensors and the deposition mask and measures, based on the detected capacitances, the gaps between the substrate and the deposition mask.

14. The deposition apparatus of claim 11, wherein:
a plurality of spacers is disposed on the deposition mask and face the measurement electrodes of the sensors, and
the signal detector respectively detects capacitances between the measurement electrodes of the sensors and the plurality of spacers and measures, based on the detected capacitances, the gaps between the substrate and the deposition mask.

15. The deposition apparatus of claim 9, wherein:
the deposition mask comprises mask cell regions, a grid region disposed between the mask cell regions, and an edge region, and
each of the plurality of sensors comprises:
a measurement electrode disposed on the grid region;
a contact pad disposed on the edge region; and
a wiring disposed on the grid region and connecting the measurement electrode and the contact pad.

16. The deposition apparatus of claim 15, further comprising a signal detector comprising a plurality of probe pins in contact with contact pads of the plurality of sensors.

17. The deposition apparatus of claim 16, wherein:
the signal detector is disposed in the mask chuck,
the deposition mask has a sensor opening exposing the contact pads, and
the plurality of probe pins are brought into contact with the contact pads through the sensor opening.

18. The deposition apparatus of claim 16, wherein the signal detector respectively detects capacitances between measurement electrodes of the sensors and the substrate and measures, based on the detected capacitances, the gaps between the substrate and the deposition mask.

19. The deposition apparatus of claim 9, further comprising a plurality of gap sensors for measuring gaps between the substrate chuck and the mask chuck,
wherein the substrate chuck driver adjusts the inclination of the substrate chuck based on measurements of the gaps between the substrate chuck and the mask chuck as provided by the plurality of gap sensors in association with adjusting a parallelism between the substrate chuck and the mask chuck.

20. An electronic device comprising a display panel comprising a substrate and light emitting material layers formed on the substrate using a deposition apparatus that comprises:
a deposition source providing a deposition material onto the substrate;
a mask chuck disposed above the deposition source and supporting a deposition mask;
a substrate chuck disposed above the mask chuck and supporting the substrate such that the substrate faces the deposition mask; and
a substrate chuck driver adjusting a position and an inclination of the substrate chuck in association with positioning the substrate on the deposition mask and adjusting a parallelism between the substrate and the deposition mask,
wherein a plurality of sensors for measuring gaps between the substrate and the deposition mask are disposed on the substrate or the deposition mask, and
the substrate chuck driver adjusts the inclination of the substrate chuck based on measurements of the gaps between the substrate and the deposition mask as provided by the plurality of sensors.
